(19) United States
(12) Patent Application Publication
(10) Pub. No.: US 2025/0307649 A1
(43) Pub. Date: Oct. 2, 2025

(54) System and Method for Cross-Domain Knowledge Transfer in Federated Compression Networks

(71) Applicant: AtomBeam Technologies Inc., Moraga, CA (US)

(72) Inventors: Zhu Li, Overland Park, KS (US); Paras Maharjan, Kansas City, MO (US); Brian Galvin, Silverdale, WA (US)

(21) Appl. No.: 19/220,037

(22) Filed: May 27, 2025

Related U.S. Application Data
(63) Continuation-in-part of application No. 18/898,608, filed on Sep. 26, 2024, now Pat. No. 12,314,839.
Application No. 18/898,608 is a continuation-in-part of application No. 18/890,748, filed on Sep. 19, 2024, now Pat. No. 12,373,739.
Application No. 18/890,748 is a continuation-in-part of application No. 18/623,018, filed on Mar. 31, 2024, now Pat. No. 12,119,848.

(51) Int. Cl. G06N 3/096; G06N 3/0455; G06N 3/0495; G06N 3/098

(52) U.S. Cl. CPC G06N 3/096; G06N 3/0455; G06N 3/0495; G06N 3/098

(57) ABSTRACT

A system and method for cross-domain knowledge transfer in federated compression networks. The system enables efficient lossless data compression across diverse data types by intelligently sharing compression strategies between domains. A cross-domain knowledge transfer system identifies relationships between different data domains, adapts compression parameters accordingly, and optimizes learning processes to maximize knowledge reuse. The architecture may include a knowledge repository for storing domain features and compression patterns, domain mapping components that identify similarities, and transfer learning optimization that enables efficient adaptation with minimal examples. This approach significantly accelerates model training for new domains while improving compression performance. Applications include satellite telemetry systems where efficient compression is critical for transmitting large information sets between distant locations. The system may employ probability prediction driven arithmetic coding paired with long short-term memory networks, enhanced by cross-domain knowledge sharing that adapts successful compression strategies from one domain to another while preserving domain-specific optimization.

### CROSS-REFERENCE TO RELATED APPLICATIONS

Priority is claimed in the application data sheet to the following patents or patent applications, each of which is expressly incorporated herein by reference in its entirety:
Ser. No. 18/898,608
Ser. No. 18/890,748
Ser. No. 18/623,018

### BACKGROUND OF THE INVENTION

### Field of the Art

The present invention is in the field of data compression, and more particularly is directed to the problem of efficiently compressing large sets of data without losing information.

### Discussion of the State of the Art

Data compression plays an integral part in manipulating vast sets of information. The process allows data to be compressed into a smaller, more manageable format which allows the data to be analyzed, processed, and transferred. An ideal method for data compression attempts to preserve as much of the original information as possible while also being fast and efficient. Generally, there are two main categories of data compression: lossless compression and lossy compression.

Lossless data compression is a process where none of the original information is sacrificed in the compression process. Information that has been compressed using a lossless compression algorithm will be exactly reproduced when the information is decompressed. This process is typically used for data types such as text files, executable programs, and some images. By contrast, lossy data compression algorithms sacrifice some of the original information in the compression process to achieve higher compression ratios. When information that has been compressed using a lossy compression algorithm is decompressed, the resulting file will be similar to the original information, but some portions of the original information may be missing. This method is generally reserved for file types such as Joint Photographic Experts Groups (JPEGs), Moving Picture Experts Groups (MPEGs), and MPEG Audio Layer III (MP3) files. With JPEGs, MPEGs, and MP3s, original information can still be identified even if some information is lost after the compression and decompression process. A third approach to data compression is transform coding where information is translated into a domain separate from the original domain. This process includes processes such as Discrete Cosine Transforms (DCT) and Discrete Wavelet Transforms (DWT) which are most commonly associated with the compression of images and audio files.

One area where data compression has become exceedingly important is related to telemetry, tracking, and command (TT&C) subsystems which are used in satellite systems. TT&C subsystems play a crucial role in facilitating essential communications between satellites and ground stations. In many cases, TT&C subsystems are the sole means through which satellites' operations and status can be monitored and controlled remotely from earth. Many satellite systems demand transmitting massive quantities of information over large distances; a process which becomes exponentially easier when the information is compressed.

What is needed is a system and method for learning-based lossless data compression where information can be reliably and efficiently compressed with low-latency and without the loss of information during compression. By integrating a plurality of neural networks into a compression system and method, information can be reliably compressed with low-latency and high efficiency all while keeping the original information intact throughout the process.

### SUMMARY OF THE INVENTION

Accordingly, the inventor has conceived and reduced to practice, system and method for cross-domain knowledge transfer in federated compression networks. The system and method proposed allow for fast and efficient lossless data compression of a large variety of data types. The system and method have a variety of real-world applications, including deep learning solutions for telemetry, tracking, and command subsystems for satellites. Because satellites and their control centers are incredibly spaced apart, data compression for information flowing between the two needs to be low-latency and high efficiency. Additionally, the proposed system and method utilize probability prediction driven arithmetic coding which provide faster encoding times and higher compression ratios when paired with a long short-term memory system for data compression.

According to a preferred embodiment, a computer system comprising a hardware memory, wherein the computer system is configured to execute software instructions stored on nontransitory machine-readable storage media that: process input data through an edge server to generate a plurality of compressed data; transmit the plurality of compressed data to a midserver, wherein the midserver converts the plurality of compressed data into a plurality of codewords using a codebook; transmit the plurality of codewords to a centralized server where the plurality of codewords are converted to a plurality of universal codewords using a universal codebook; analyze domain characteristics of the compressed data and identify relationships with existing domains using a plurality of similarity metrics; adapt compression strategies across different domains using transfer learning optimization to accelerate model training with domain-specific examples; train a large codeword model core using the plurality of universal codewords; and deploy a trained large codeword model core wherein the large codeword model core receives a plurality of input data and generates a plurality of compressed outputs, is disclosed.

According to another preferred embodiment, a method for federated two-stage compression with federated joint learning, comprising the steps of: processing input data through an edge server to generate a plurality of compressed data; transmitting the plurality of compressed data to a midserver, wherein the midserver converts the plurality of compressed data into a plurality of codewords using a codebook; transmitting the plurality of codewords to a centralized server where the plurality of codewords are converted to a plurality of universal codewords using a universal codebook; analyzing domain characteristics of the compressed data and identify relationships with existing domains using a plurality of similarity metrics; adapting compression strategies across different domains using transfer learning optimization to accelerate model training with domain-specific examples; training a large codeword model core using the plurality of universal codewords; and deploying a trained large codeword model core wherein the large codeword model core receives a plurality of input data and generates a plurality of compressed outputs, is disclosed.

According to an aspect of an embodiment, the large codeword model core functions using a Transformer based architecture.

According to an aspect of an embodiment, the Variational Autoencoder with Vector Quantization and the large codeword model core are jointly trained.

### BRIEF DESCRIPTION OF THE DRAWING FIGURES

FIG. 1 is a block diagram illustrating an exemplary system architecture for learning-based lossless data compression.

FIG. 2 is a block diagram illustrating an exemplary architecture for a subsystem of the system for learning-based lossless data compression, a multilayer perceptron system.

FIG. 3 is a block diagram illustrating an exemplary architecture for a subsystem of the system for learning-based lossless data compression, a long short-term memory system.

FIG. 4 is a block diagram illustrating an exemplary machine learning model for either the multilayer perceptron system or the long short-term memory system.

FIG. 5 is a flow diagram illustrating an exemplary method of learning-based data compression.

FIG. 6 is a block diagram illustrating an exemplary system architecture for a system and for federated two-stage compression with federated joint learning.

FIG. 7 is a block diagram illustrating an exemplary system architecture for a trainable compression network on an edge server.

FIG. 8 is a flow diagram illustrating an exemplary method for federated two-state compression with federated joint learning.

FIG. 9 is a flow diagram illustrating an exemplary method for a training and utilizing a compression network on an edge server.

FIG. 10 is a block diagram illustrating an exemplary system architecture for a system for federated two-stage compression with federated joint learning that uses a VAE-VQ and a transformer based large codeword core.

FIG. 11 is a block diagram illustrating an exemplary architecture for a subsystem of a system for federated two-stage compression with federated joint learning, a transformer based large codeword model core.

FIG. 12 is a block diagram illustrating an exemplary architecture for a subsystem of a system for federated two-stage compression with federated joint learning, a Variatitional Autoencoder with Vector Quantization (VAE-VQ) based compression network.

FIG. 13 is a flow diagram illustrating an exemplary method for federated two-state compression with federated joint learning using a VAE-VQ and a transformer.

FIG. 14 is a block diagram illustrating an exemplary system architecture for a system for federated two-stage compression with federated joint learning that incorporates a cross-domain knowledge transfer system.

FIG. 15 is a block diagram illustrating the detailed internal architecture of a cross-domain knowledge transfer system.

FIG. 16 is a flow diagram illustrating an exemplary method for cross-domain knowledge acquisition and repository management within the federated two-stage compression system.

FIG. 17 is a flow diagram illustrating an exemplary method for domain mapping and adaptation within the federated two-stage compression system.

FIG. 18 is a flow diagram illustrating an exemplary method for transfer learning optimization within the federated two-stage compression system.

FIG. 19 illustrates an exemplary computing environment on which an embodiment described herein may be implemented, in full or in part.

### DETAILED DESCRIPTION OF THE INVENTION

The inventor has conceived, and reduced to practice, a system and method for cross-domain knowledge transfer in federated compression networks.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods, and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Conceptual Architecture

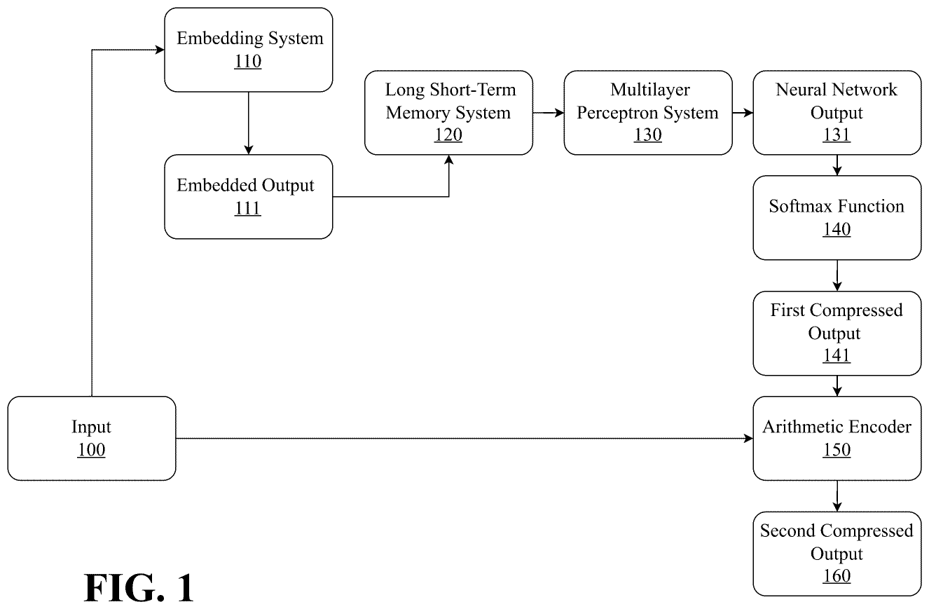

FIG. 1 is a block diagram illustrating an exemplary system architecture for learning-based lossless data compression. In one embodiment, the system and method may comprise an input 100, an embedding system 110, an embedded output 111, a long short-term memory system (LSTM) 120, a multilayer perceptron system 130, a neural network output 131, a SoftMax function 140, a first compressed output 141, an arithmetic encoder 150, and a second compressed output 160. In one embodiment, the embedding system 110 receives the input 100 or plurality of inputs 100 from a source. The input 100 may include, but is not limited to a text file, a video file, an audio file, or any other file which includes a plurality of information. The embedding system 110 prepares an input 100 for further processing by a plurality of neural network systems. The embedding system 110 turns the input 100 into an embedded output 111 which may then be processed by a long short-term memory system 120.

In one embodiment, the long short-term memory system 120 is a plurality of recurring neural network architectures which further processes the embedded output 111 for compression. The LSTM 120 is a special kind of recurring neural network where the present output depends on the LSTM's understanding of the previous output. The LSTM 120 is capable of learning long term dependency through the use of a plurality of gates that allows the LSTM 120 to add and remove information to a cell state. After an embedded output 111 is processed by the LSTM 120, the embedded output 111 is processed by the multilayer perceptron system 130. The multilayer perceptron system (MLP) 130 is a neural network which uses a PAQ algorithm to achieve data compression. A PAQ algorithm refers to a plurality of lossless data compression algorithms which are exceptionally effective and have high compression ratios for many different data types. In one embodiment, the MLP 130 may be a shallow MLP where a plurality of inputs are operated on by a plurality of weights which creates a large linear plurality of hidden nodes which are grouped into sets. The plurality of hidden nodes may be operated on a small plurality of additional weights which converges the hidden nodes into a single output node. A key feature of a shallow MLP 130 is that the plurality of hidden nodes are operated on by the additional weights in one step, rather than a plurality of steps. In one embodiment, the embedded output 111 which has been processed by the LSTM 120 is transformed by the MLP 130 which may be a shallow MLP 130 into a neural network output 131. The neural network output 131 may then be operated on by a SoftMax function 140 which generates a compressed output 141. The compressed output 141 is a compressed version of the input 100 where no information has been lost during the compression process.

In another embodiment, the first compressed output 141 may then be passed to an arithmetic encoder 150 which may also receive the input 100. The arithmetic encoder 150 may generate a probability output by analyzing and processing the input 100 and the first compressed output 141. The arithmetic encoder 150 may also receive the input 100 and the first compressed output 141 where it generates a second compressed output 160. Generally, an arithmetic encoder receives a string with a length which is compressed to the shortest byte string which represents a number (X) within a particular range. In some embodiments, the arithmetic encoder 150 may be an arithmetic encoder in PAQ. An arithmetic encoder in PAQ maintains for each prediction an upper and lower limit on X. Concluding each prediction, the current range of X is split into parts representing the probabilities that the next bit of the string is either a 0 or a 1, which may be based on previous bits of the string. The next bit may then be encoded by selecting a new range to take place of the previous range of X. Generally, the upper and lower limits are represented in three segments. The first segment generally has the same base-256 digits and are often presented as the leading bytes of X. The next segment is generally stored in memory which the first digit in the segment varies from the remaining digits. The remaining segment is generally assumed to be zeros for the lower limit and ones for the upper limit. In one embodiment, compression may cease when one or more bytes are written from the lower bound of X.

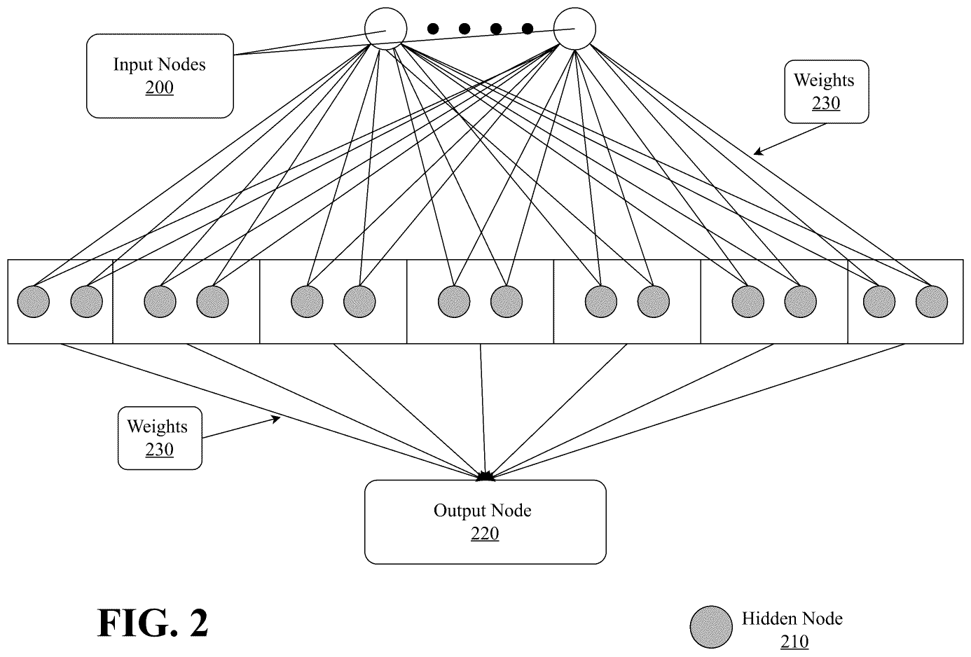

FIG. 2 is a block diagram illustrating an exemplary architecture for a subsystem of the system for learning-based lossless data compression, a multilayer perceptron system 130. In an embodiment, the multilayer perceptron system 130 may receive a plurality of inputs which begin as input nodes 200. The plurality of input nodes 200 are operated on by a plurality of predetermined weights. The plurality of predetermined weights 230 creates a plurality of hidden nodes 210 which may exist in a grouped sequence. In one embodiment, there may be 552 input nodes where are operated on by 3080 weights. This creates 3080 new hidden nodes which exist in seven sets, each set containing a plurality of hidden nodes 210. Each set of hidden nodes 210 is then operated on by an additional layer of weights 230 which may or may not be similar to the weights used on the input nodes. In embodiment where the hidden nodes 210 exist in seven sets, there will be seven additional weights. The additional weights act on the sets of hidden nodes 210 to create a plurality of output nodes 220.

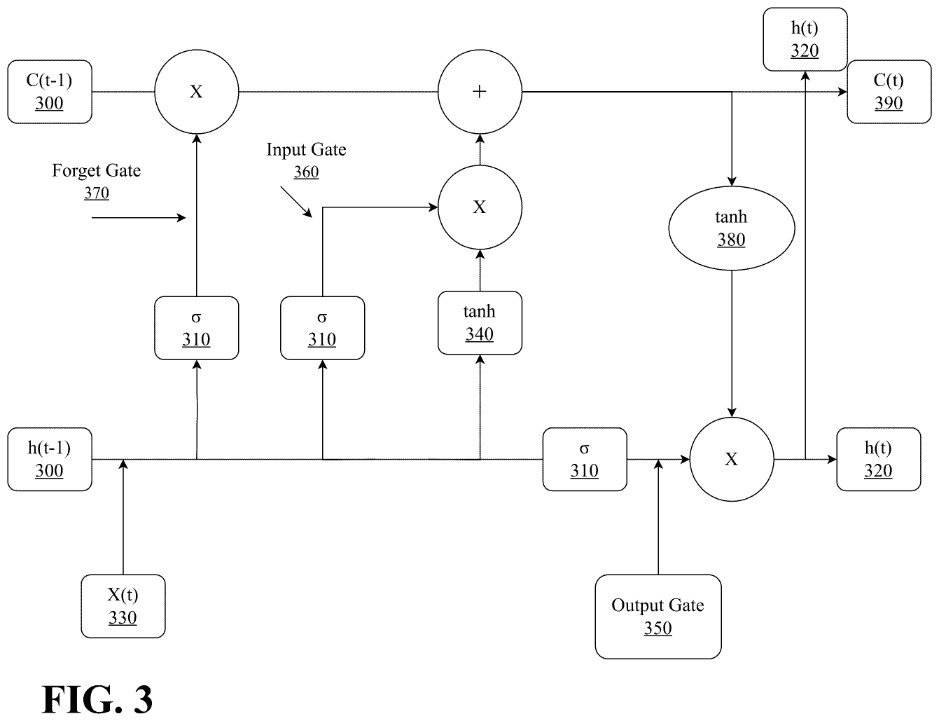

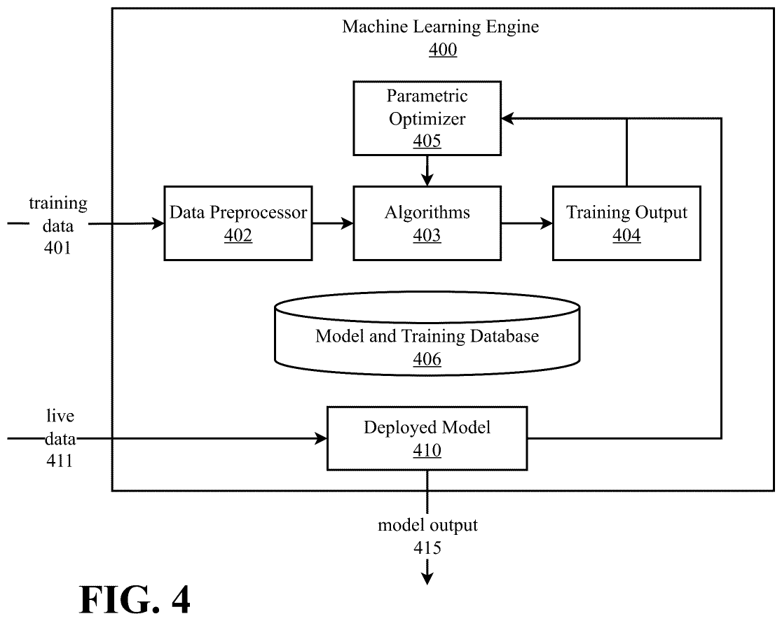

FIG. 3 is a block diagram illustrating an exemplary architecture for a subsystem of the system for learning-based lossless data compression, a long short-term memory system 120. In one embodiment, the LSTM system 120 is further comprised of a plurality of functions where the present output depends on understanding the previous output. The LSTM system 120 is capable of learning long term dependency and a plurality of gates allow the system to add and remove information to a cell state. The flow state in FIG. 4 may be governed by the following functions in one embodiment:

$$\begin{matrix}{i}_{t} = σ ( {W}_{ix} {x}_{t} + {W}_{ih} {h}_{t - 1} + {b}_{i} ) \\ {f}_{t} = σ ( {W}_{fx} {x}_{t} + {W}_{fh} {h}_{t - 1} + {b}_{f} ) \\ {O}_{t} = σ ( {W}_{ox} {x}_{t} + {W}_{oh} {h}_{t - 1} + {b}_{o} ) \\ {c}_{t} = {f}_{t} ⊙ {c}_{t - 1} + {i}_{t} ⊙ tanh ( {W}_{cx} {x}_{t} + {W}_{ch} {h}_{t - 1} + {b}_{c} ) \\ {h}_{t} = {0}_{t} ⊙ tanh ( {c}_{t} )\end{matrix}$$

Where iₜ represents an input gate 360, fₜ represents a forget gate 370, and Oₜ represents an output gate 350. The forget gate 370 allows the system to remove information from a cell state, the input gate 360 allows the system to add information to a cell state, and the output gate 350 allows the system to output information from a cell state.

### Detailed Description of Exemplary Aspects

FIG. 4 is a block diagram illustrating an exemplary machine learning model for either the multilayer perceptron system or the long short-term memory system. According to the embodiment, the multilayer perceptron system 130 or the long short-term memory system 120 may comprise a machine learning engine 400 which may further comprise a model training stage comprising a data preprocessor 402, one or more machine and/or deep learning algorithms 403, training output 404, and a parametric optimizer 405, and a model deployment stage comprising a deployed and fully trained model 410 configured to perform tasks described herein such as transcription, summarization, agent coaching, and agent guidance. Machine learning engine 400 may be used to train and deploy a long short-term memory system 120 and the multilayer perceptron system 130 in order to support the services provided by the lossless data compression system.

At the model training stage, a plurality of training data 401 may be received by the machine learning engine 400. In some embodiments, the plurality of training data may be obtained from one or more database(s) 108 and/or directly from various information sources such as a plurality of contact centers 120. In a use case, a plurality of training data may be sourced TT&C satellite subsystems. It could include text files, audio or video files, or other forms of data. Data preprocessor 402 may receive the input data and perform various data preprocessing tasks on the input data to format the data for further processing. For example, data preprocessing can include, but is not limited to, tasks related to data cleansing, data deduplication, data normalization, data transformation, handling missing values, feature extraction and selection, mismatch handling, and/or the like. Data preprocessor 402 may also be configured to create training dataset, a validation dataset, and a test set from the plurality of input data 401. For example, a training dataset may comprise 80% of the preprocessed input data, the validation set 10%, and the test dataset may comprise the remaining 10% of the data. The preprocessed training dataset may be fed as input into one or more machines and/or deep learning algorithms 403 to train a predictive model for object monitoring and detection.

During model training, training output 404 is produced and used to measure the accuracy and usefulness of the predictive outputs. During this process a parametric optimizer 405 may be used to perform algorithmic tuning between model training iterations. Model parameters and hyperparameters can include, but are not limited to, bias, train-test split ratio, learning rate in optimization algorithms (e.g., gradient descent), choice of optimization algorithm (e.g., gradient descent, stochastic gradient descent, of Adam optimizer, etc.), choice of activation function in a neural network layer (e.g., Sigmoid, ReLu, Tanh, etc.), the choice of cost or loss function the model will use, number of hidden layers in a neural network, number of activation unites in each layer, the drop-out rate in a neural network, number of iterations (epochs) in a training the model, number of clusters in a clustering task, kernel or filter size in convolutional layers, pooling size, batch size, the coefficients (or weights) of linear or logistic regression models, cluster centroids, and/or the like. Parameters and hyperparameters may be tuned and then applied to the next round of model training. In this way, the training stage provides a machine learning training loop. In some implementations, various accuracy metrics may be used by machine learning engine 400 to evaluate a model's performance. Metrics can include, but are not limited to, information loss, latency, and resource consumption.

A model and training database 406 is present and configured to store training/test datasets and developed models. Database 406 may also store previous versions of models. According to some embodiments, the one or more machine and/or deep learning models may comprise any suitable algorithm known to those with skill in the art including, but not limited to: LLMs, generative transformers, transformers, supervised learning algorithms such as: regression (e.g., linear, polynomial, logistic, etc.), decision tree, random forest, k-nearest neighbor, support vector machines, Naïve-Bayes algorithm; unsupervised learning algorithms such as clustering algorithms, hidden Markov models, singular value decomposition, and/or the like. Alternatively, or additionally, algorithms 403 may comprise a deep learning algorithm such as neural networks (e.g., recurrent, convolutional, long short-term memory networks, etc.).

In some implementations, ML engine 400 automatically generates standardized model scorecards for each model produced to provide rapid insights into the model and training data, maintain model provenance, and track performance over time. These model scorecards provide insights into model framework(s) used, training data, training data specifications such as chip size, stride, data splits, baseline hyperparameters, and other factors. Model scorecards may be stored in model and training database 406.

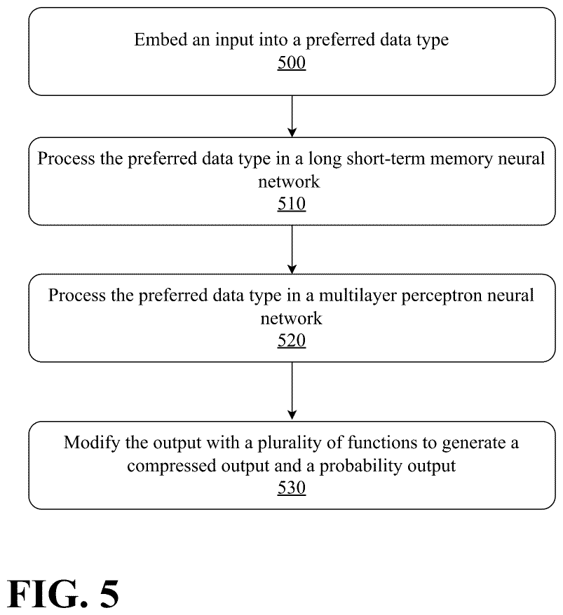

FIG. 5 is a flow diagram illustrating an exemplary method of learning-based data compression. In a first step 500, embed an input into a preferred data type. The input may be a data type including but not limited to, text files, audio files, video files, and any other data type which carries information. In a step 510, process the preferred data type in a long short-term memory neural network. In a step 520, process the preferred data type in a multilayer perceptron neural network which creates an output. In a step 530, modify the output with a plurality of functions to generate a compressed output and a probability output. The plurality of functions may include a SoftMax function and an arithmetic encoding algorithm.

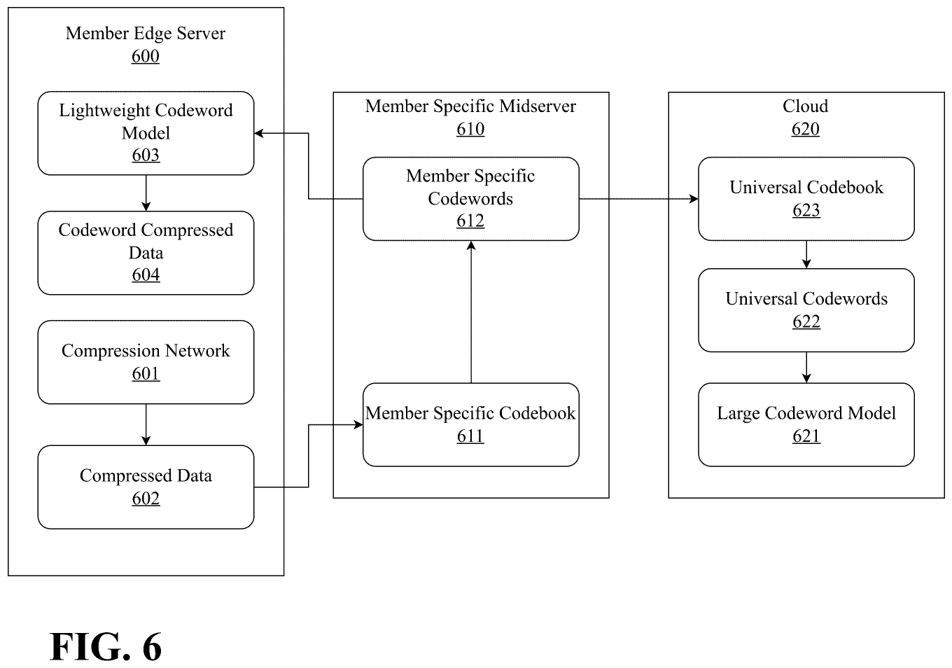

FIG. 6 is a block diagram illustrating an exemplary system architecture for a system and for federated two-stage compression with federated joint learning. Illustrated is an expanded system architecture for learning-based lossless data compression, building upon the original MLP-LSTM compression framework. The system comprises three main components: a member edge server 600, a member specific midserver 610, and a cloud 620. At the member edge server 600, a compression network 601, which may utilizes the MLP-LSTM compression technique utilized in the system for learning-based lossless data compression, processes input data to generate compressed data 602. This compressed data is then sent to the member specific midserver 610 for further processing.

The member specific midserver 610 employs a member specific codebook 611 to convert the compressed data into member specific codewords 612. These codewords represent a more compact and specialized form of the original data, tailored to the specific member's data characteristics. The member specific codewords are then relayed back to the member edge server 600, where they are used to train a lightweight codeword model 603. This model is specifically designed to handle tasks relevant to the edge server, allowing for even greater compression efficiency due to its specialized nature.

The term “lightweight codeword model” is used to describe a specialized model designed to operate efficiently on edge servers with limited computational resources. This model is considered “lightweight” because it is tailored to handle a specific, narrow set of tasks relevant to the particular edge server, rather than being a comprehensive model capable of processing a wide range of data types. The model is “codeword-based” because it operates on the codewords generated from the compressed data, which represent a more compact and efficient form of the original information.

The specialization of the lightweight codeword model to the edge server's specific data and tasks allows for greater efficiency and compression. For example, an edge server in a smart factory might have a lightweight codeword model specialized for processing sensor data from manufacturing equipment. This model would be highly efficient at compressing and analyzing data related to machine performance, temperature readings, and production metrics, but it wouldn't need to handle unrelated tasks like image recognition or natural language processing. Similarly, an edge server in an autonomous vehicle might have a lightweight codeword model optimized for processing real-time data from various sensors, cameras, and GPS systems. This model would be extremely efficient at compressing and analyzing data related to vehicle position, obstacle detection, and traffic conditions, but it wouldn't need to handle tasks irrelevant to driving. In both cases, the lightweight nature of the model, combined with its specialization to a specific set of codewords representing compressed data from a narrow domain, allows for rapid processing and highly efficient compression on resource-constrained edge devices.

In another example, an edge server in a smart home environment might use its lightweight codeword model to efficiently process and compress sensor data from various IoT devices. Another instance could be a mobile edge server utilizing its lightweight model to compress and analyze user interaction data in real-time, optimizing app performance and responsiveness.

In addition to training the lightweight model, the member specific codewords may also sent to the cloud 620 for broader analysis and model training. The cloud environment contains a universal codebook 623 that integrates the member specific codewords from various sources into a comprehensive set of universal codewords 622. These universal codewords serve as input for training a large codeword model 621 in the cloud. This larger model has broader implications and can capture patterns and insights across multiple members or data sources.

The system also allows for bidirectional flow of information. The lightweight codeword model on the edge server can be updated based on insights from the large codeword model in the cloud, ensuring that edge processing remains efficient and up-to-date. Similarly, the cloud model continuously evolves as it receives new codewords from various member specific midservers. The system is designed to support federated learning, allowing multiple member edge servers and their associated midservers to collaboratively train and improve the compression models without sharing raw data. This federated approach ensures data privacy while leveraging the collective knowledge of all participants.

In the federated learning process, each member edge server 600 trains its own version of the compression network 601 and lightweight codeword model 603 on its local data. Instead of sharing the raw data or compressed data, only the model updates (such as weights or gradients) may be sent to the cloud 620. The cloud aggregates these updates from multiple members to improve the large codeword model 621, which serves as the global model in this federated system.

The system also enables federated joint learning, where the entire pipeline—from the initial compression network to the final large codeword model—is optimized end-to-end across all participating members. This joint learning process allows the system to find the optimal balance between compression efficiency at the edge, codeword generation at the midserver, and global model performance in the cloud. During federated joint learning, the cloud 620 periodically sends updates to the member specific midservers 610 and edge servers 600. These updates help refine the member specific codebooks 611 and improve the performance of the lightweight codeword models 603 on the edge servers. This bidirectional flow of model updates ensures that each component of the system benefits from the collective learning process while maintaining the privacy of individual member data.

The federated joint learning approach also allows for personalization. While the large codeword model 621 in the cloud captures general patterns across all members, each member's lightweight codeword model 603 can be fine-tuned to its specific data distribution and tasks. This personalization improves the efficiency of edge processing while still benefiting from the broader knowledge captured in the global model.

By combining federated learning with joint optimization, this system achieves a balance between local efficiency, global performance, and data privacy. It enables collaborative learning across multiple members or organizations without the need to centralize sensitive data, making it particularly suitable for applications where data privacy and edge computing efficiency are crucial. This multi-tiered approach combines the benefits of edge computing, specialized compression, and cloud-based large-scale modeling. It enables efficient data processing and compression at the edge, while also facilitating broader analysis and model development in the cloud, all while maintaining data privacy through the use of codewords rather than raw data.

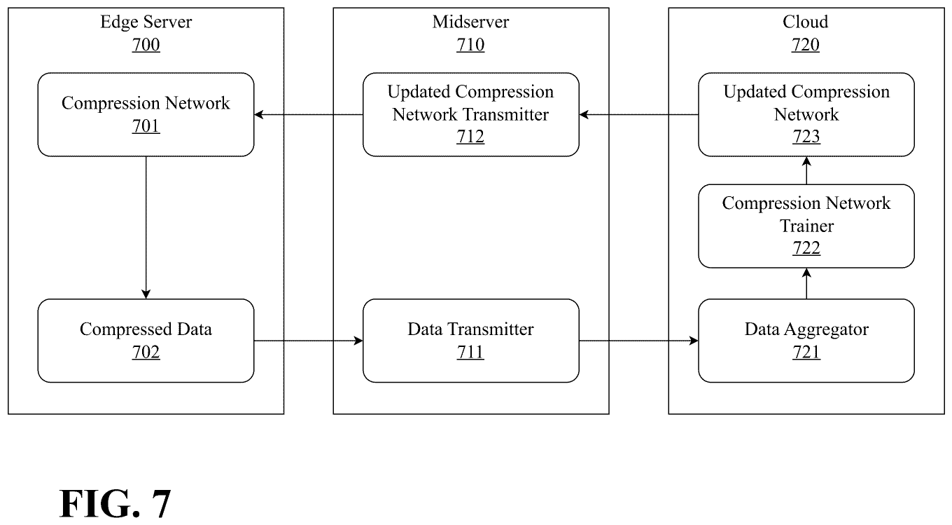

FIG. 7 is a block diagram illustrating an exemplary system architecture for a trainable compression network on an edge server. Depicted is a training cycle for a learning-based lossless data compression system, comprising three main components: an edge server 700, a midserver 710, and a cloud environment 720. This system demonstrates how compressed data from the edge is used to update the compression model, which is then redistributed back to the edge.

At the edge server 700, a compression network 701 processes input data to generate compressed data 702. The compression network may utilize advanced techniques such as the MLP-LSTM framework disclosed in the lossless data compression system. The compressed data 702 represents a compact form of the original information, optimized for efficient storage and transmission.

The compressed data 702 is then sent to the midserver 710, which acts as an intermediary between the edge and the cloud. The midserver contains a data transmitter 711 that securely forwards the compressed data to the cloud environment. This transmission step ensures that only the compressed form of the data, rather than raw information, leaves the edge server, enhancing data privacy and reducing bandwidth requirements. In the cloud environment 720, a data aggregator 721 collects compressed data from multiple sources, potentially including various edge servers and midservers. This aggregated data serves as input for the compression network trainer 722. The trainer analyzes the compressed data to identify patterns, inefficiencies, or areas for improvement in the current compression model.

Based on this analysis, the compression network trainer 722 updates the existing model, producing an updated compression network 723. This updated network incorporates learnings from the aggregated compressed data, potentially improving compression efficiency, accuracy, or adaptability to different types of input data. The updated compression network 723 is then sent back to the midserver 710, where an updated compression network transmitter 712 manages its secure distribution back to the edge server 700. Once received, the edge server can replace its existing compression network 701 with the updated version, completing the training cycle.

This cyclical process allows for continuous improvement of the compression model based on real-world data. By aggregating compressed data from multiple sources in the cloud, the system can learn from a diverse range of inputs, potentially leading to a more robust and efficient compression network. At the same time, by only transmitting compressed data and updated models, rather than raw data, the system maintains a high level of data privacy and efficiency. The use of a midserver 710 as an intermediary adds an extra layer of security and control, potentially allowing for additional data processing or filtering steps between the edge and the cloud. This architecture also provides flexibility, as the midserver could be tailored to specific organizational needs or regulatory requirements.

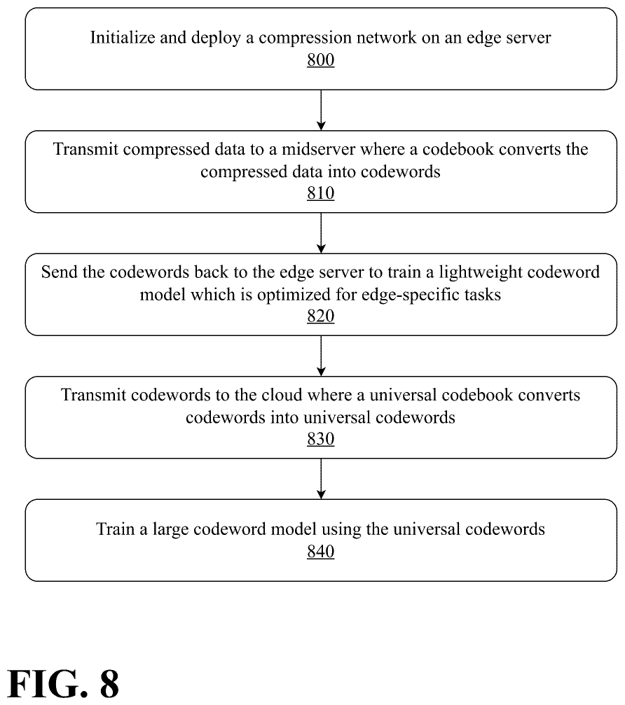

FIG. 8 is a flow diagram illustrating an exemplary method for federated two-state compression with federated joint learning. In a first step 800, a compression network is initialized and deployed on an edge server. This step involves setting up the initial architecture of the compression network, which could be based on the MLP-LSTM framework mentioned in the original patent. The network is configured to efficiently compress data specific to the edge server's tasks. For example, in a smart home system, this network might be optimized to compress data from various IoT devices such as thermostats, security cameras, and energy meters.

In a step 810, the compressed data is transmitted to a midserver where a codebook converts the compressed data into codewords. This step involves sending the output of the compression network to a separate server that acts as an intermediary. The midserver uses a predefined codebook to transform the compressed data into a series of codewords. These codewords represent a more compact form of the data, further reducing its size while maintaining its essential information. For instance, in our smart home example, a sequence of compressed temperature readings might be converted into a single codeword representing a specific temperature pattern.

In a step 820, the codewords are sent back to the edge server to train a lightweight codeword model which is optimized for edge-specific tasks. This step is crucial for improving the efficiency of edge processing. The lightweight model learns to interpret and work directly with the codewords, allowing for faster processing and decision-making at the edge. In our smart home scenario, this model might learn to quickly identify unusual temperature patterns or predict energy usage based on the codewords, without needing to decompress the full data.

In a step 830, the codewords are transmitted to the cloud where a universal codebook converts them into universal codewords. This step broadens the scope of the data representation. The universal codebook in the cloud can interpret codewords from multiple sources and convert them into a standardized format. For example, it might convert temperature pattern codewords from various smart home systems into universal codewords that represent general climate trends.

In a step 840, a large codeword model is trained using the universal codewords. This step involves using the standardized, universal codewords to train a more comprehensive model in the cloud. This model can capture broader patterns and insights across multiple edge servers or even different types of systems. In the ongoing example, this large model might learn to identify correlations between temperature patterns, energy usage, and other factors across many smart homes, potentially leading to improved energy management strategies or predictive maintenance for HVAC systems.

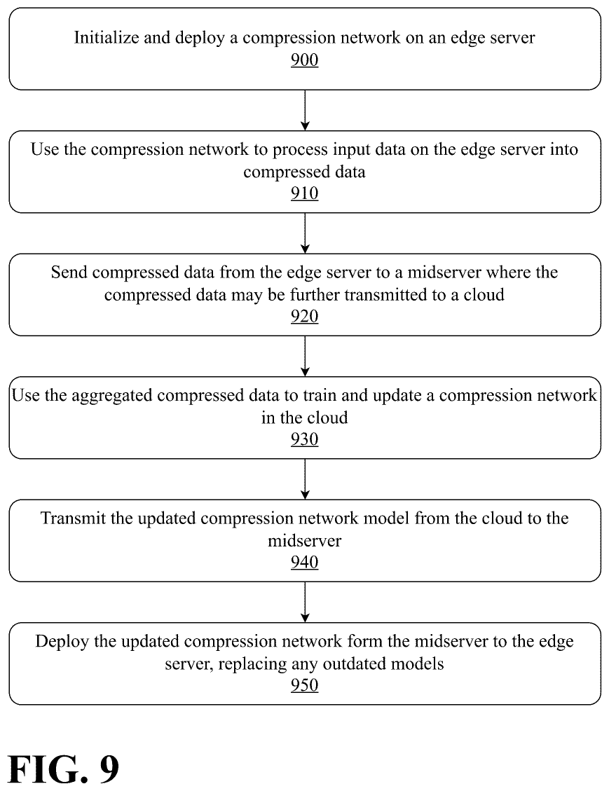

FIG. 9 is a flow diagram illustrating an exemplary method for a training and utilizing a compression network on an edge server. In a first step 900, a compression network is initialized and deployed on an edge server. This step involves setting up the initial architecture of the compression network, which could be based on advanced techniques such as the MLP-LSTM framework. The network is configured to efficiently compress data specific to the edge server's tasks and environment. For instance, in a smart city traffic management system, this network might be optimized to compress data from traffic cameras, speed sensors, and vehicle counters.

In a step 910, the compression network is used to process input data on the edge server, generating compressed data. This step involves applying the current version of the compression network to incoming data streams, reducing their size while preserving essential information. In the smart city example, the network might compress real-time traffic flow data, reducing high-resolution video feeds to key metrics like vehicle count, average speed, and lane occupancy.

In a step 920, the compressed data is sent from the edge server to a midserver where it may be further transmitted to a cloud. The midserver acts as an intermediary, facilitating secure and efficient data transfer between the edge and the cloud. This step ensures that only compressed, privacy-preserving data leaves the edge environment. In the traffic management scenario, the midserver might aggregate compressed data from multiple intersections before sending it to the cloud.

In a step 930, the aggregated compressed data is used to train and update a compression network in the cloud. A compression network trainer in the cloud analyzes the collected data from multiple sources, identifying patterns and areas for improvement in the current model. For the smart city example, this might involve learning new patterns in traffic flow across different times of day, weather conditions, or special events, allowing the model to more efficiently compress and represent these scenarios.

In a step 940, the updated compression network model is transmitted from the cloud back to the midserver. This step involves securely sending the newly trained model through the network for distribution to edge servers. The updated model incorporates learnings from a wide range of data sources, potentially improving its ability to compress diverse types of traffic data more efficiently. In a step 950, the updated compression network is deployed from the midserver to the edge server, replacing any outdated models. This completes the training cycle, with the edge server now using an improved model based on aggregated data from multiple sources. In our traffic management system, this could result in more efficient compression of traffic data, potentially allowing for real-time analysis of more data streams or freeing up computational resources for other tasks.

This cyclical process allows for continuous improvement of the compression model, leveraging both edge and cloud computing resources to optimize performance and efficiency over time. It enables the system to adapt to changing data patterns and improve its compression capabilities without requiring manual intervention at each edge server. The use of midservers adds an extra layer of security and control, potentially allowing for additional data processing or filtering steps between the edge and the cloud.

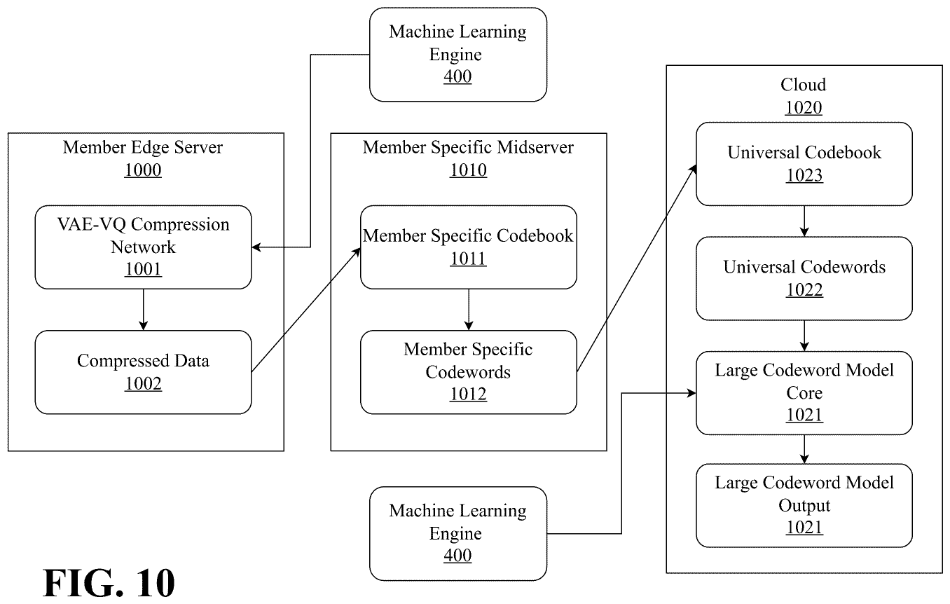

FIG. 10 is a block diagram illustrating an exemplary system architecture for a system for federated two-stage compression with federated joint learning that uses a VAE-VQ and a transformer based large codeword core. The system comprises three main components: a member edge server 1000, a member specific midserver 1010, and a cloud environment 1020.

At the member edge server 1000, a Variational Autoencoder with Vector Quantization (VAE-VQ) compression network 1001 is employed to compress input data. This network combines a Variational Autoencoder (VAE) with Vector Quantization VQ to achieve efficient data compression. The VAE part of the network encodes input data into a latent space representation, which is then quantized using a discrete codebook in the VQ part. This process maps the continuous latent space to a finite set of discrete vectors, enabling more efficient compression. The VAE-VQ network is particularly effective for compressing complex, high-dimensional data while preserving important features. The compressed data 1002 produced by this network is then sent to the member specific midserver 1010 for further processing.

The member specific midserver 1010 employs a member specific codebook 1011 to convert the compressed data into member specific codewords 1012. This codebook is tailored to the specific data characteristics of the member, allowing for more efficient representation of the compressed data. The member specific codewords are then transmitted to the cloud 1020 for final processing.

In the cloud environment 1020, a universal codebook 1023 is used to transform the member specific codewords into universal codewords 1022. These universal codewords serve as the input for the large codeword model core 1021, which processes the data and produces a large codeword model output 1021.

The large codeword model core 1021 could be implemented using various deep learning architectures. One prominent example is a Transformer model, which has shown exceptional performance in processing sequential data. Transformers use self-attention mechanisms to capture long-range dependencies in the input data, making them well-suited for processing codeword sequences. Alternatively, the core could be implemented as a Diffusion model, which has shown promising results in generative tasks by learning to reverse a gradual noising process. Other potential architectures could include large language models (LLMs) adapted for codeword processing, or custom neural network designs optimized for the specific requirements of codeword-based data representation.

Both the member specific midserver 1010 and the cloud 1020 may be trained by the machine learning engine 400. This engine is responsible for training and updating the respective components of the system, including the member specific codebook, universal codebook, and the large codeword model core. The machine learning engine ensures that the system continually adapts and improves based on the processed data. Each machine learning component in the system may be jointly trained before development. Additionally, the system has the capability of individually training single systems as needed.

This multi-tiered approach combines the benefits of edge computing, specialized compression, and cloud-based large-scale modeling. It enables efficient data processing and compression at the edge using the VAE-VQ network, further compression and specialization at the midserver level, and sophisticated analysis and model development in the cloud. The use of codebooks and codewords at various stages allows for efficient data representation while maintaining privacy, as the original data is never directly shared beyond the edge server.

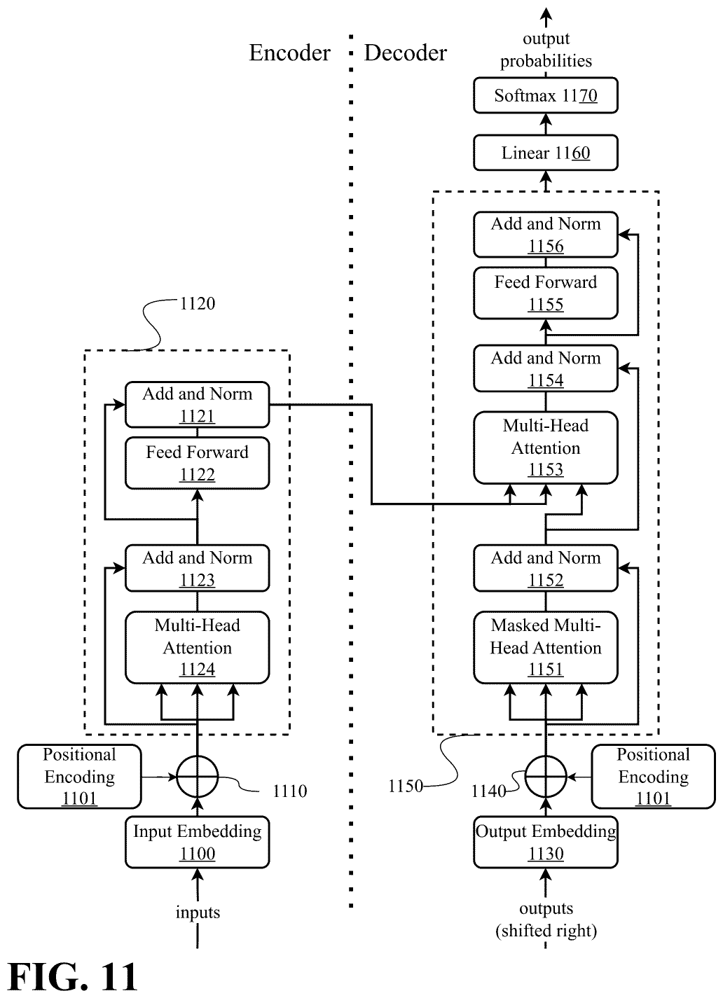

FIG. 11 is a block diagram illustrating an exemplary architecture for a subsystem of a system for federated two-stage compression with federated joint learning, a transformer based large codeword model core. In one embodiment, the large codeword model core may utilize a transformer based deep learning architecture. A Transformer generally comprises an Encoder (the components on the left side of the illustration) and a Decoder (the components on the right side of the illustration).

The illustrated Transformer comprises an Encoder and a Decoder. The Encoder takes input embeddings and processes them through a stack of layers (represented as dashed box 1120). Each layer consists of: positional encoding, which adds position information to the input embeddings; multi-head attention, which allows the model to attend to different parts of the input sequence; add and norm, which applies residual connection and layer normalization; feed forward, which is a fully connected feed-forward network; and add and norm which is another residual connection and layer normalization.

The power of the transformer model lies in the self-attention mechanism. This mechanism contributes to accelerated learning compared to traditional models such as long short-term memory models. Self-attention empowers the transformer model with the remarkable capability to meticulously scrutinize distinct segments of a given sequence or even encompass the entire contextual essence of a sentence. This profound contextual awareness enables the model to make predictions with an elevated degree of accuracy and relevance.

The input embedding 1100 to the Encoder is a sequence of tokens, typically represented as integers. Each token is mapped to a learnable embedding vector of a fixed size. The embedding layer is a lookup table that converts each token into its corresponding dense vector representation. The embeddings are learned during training and capture semantic and syntactic relationships between tokens.

A dense vector representation, also known as a dense embedding or a continuous vector representation, is a way of representing data, particularly words or tokens, as dense vectors in a high-dimensional continuous space. In the context of natural language processing (NLP) and language models, dense vector representations are used to capture semantic and syntactic information about words or tokens. Each word or token is mapped to a fixed-size vector of real numbers, typically with hundreds or thousands of dimensions. Each word or token is represented by a vector of a fixed size, regardless of the length of the input sequence. The size of the vector is a hyperparameter that is determined during model design. The vectors exist in a continuous high-dimensional space, where each dimension represents a latent feature or aspect of the word or token. The continuous nature allows for capturing fine-grained relationships and similarities between words. The dense vector representations are learned during the training process of the model. The model learns to assign similar vectors to words that have similar meanings or occur in similar contexts. The dense vector representations aim to capture semantic and syntactic relationships between words. Words that have similar meanings or are used in similar contexts tend to have similar vector representations. Dense vector representations allow for performing algebraic operations on words, such as addition and subtraction. These operations can capture analogies and relationships between words, such as “prince”−“man”+“woman”≈“princess”. Dense vector representations serve as input features for various downstream NLP tasks, such as text classification, sentiment analysis, named entity recognition, and machine translation. The dense representations provide a rich and informative input to the models, enabling them to learn patterns and make predictions. Some popular examples of dense vector representations include, but are not limited to, Word2Vec, Global Vectors for Word Representations (GloVe), FastText, and BERT.

After the input embedding layer, positional encoding 1101 is added to the input embedding to provide position information to the model. The positional encoding 1101 and the input embedding 1100 may be added using a function 1110. Since the Transformer architecture doesn't have inherent recurrence or convolution, positional encodings help capture the order and relative positions of tokens. The positional encodings are typically sine and cosine functions of different frequencies, allowing the model to learn relative positions. The positional encodings have the same dimensionality as the input embeddings and are summed with them.

The Encoder utilizes a multi-head attention mechanism 1124 which is a key component of the Transformer architecture. It allows the Encoder to attend to different parts of the input sequence and capture dependencies between tokens. The attention mechanism computes three matrices: Query (Q), Key (K), and Value (V). The Query, Key, and Value matrices are obtained by linearly projecting the input embeddings using learned weight matrices. The attention scores are computed by taking the dot product of the Query matrix with the transpose of the Key matrix, followed by scaling and applying a softmax function. The attention scores determine the importance of each token in the input sequence for a given position. The Value matrix is then multiplied with the attention scores to obtain the weighted sum of the values, which forms the output of the attention mechanism. Multi-Head Attention splits the Query, Key, and Value matrices into multiple heads, allowing the model to attend to different aspects of the input simultaneously. The outputs from each head are concatenated and linearly projected to obtain the final output of the Multi-Head Attention layer 1124.

After the Multi-Head Attention layer, a residual connection is applied, followed by Layer Normalization at add and norm 1123. The residual connection adds the input embeddings to the output of the attention layer, helping the model learn faster and deeper. Layer Normalization normalizes the activations across the features, stabilizing the training process.

The Feed Forward layer 1122 is a fully connected neural network applied to each position of the Encoder's hidden states. It consists of two linear transformations with a Rectified Linear Unit (ReLU) activation function in between. The purpose of the Feed Forward layer is to introduce non-linearity and increase the model's capacity to learn complex representations. The output of the Feed Forward layer has the same dimensionality as the input embeddings. A residual connection and Layer Normalization 1121 are applied after the Feed Forward layer.

The Encoder layers 1120 are stacked Nx times, where N is a hyperparameter that determines the depth of the Encoder. Each layer follows the same structure: Multi-Head Attention, Add & Norm, Feed Forward, and Add & Norm. By stacking multiple Encoder layers, the model can capture hierarchical and long-range dependencies in the input sequence. The output of the final Encoder layer represents the encoded input sequence, which is then passed to the Decoder for generating the output sequence.

The Decoder generates the output probabilities. It has a similar structure to the Encoder, with a few additions. The Decoder takes output embeddings and processes them through a stack of layers (represented as dashed box 1150). The output embedding layer 1130 takes the previous output tokens (shifted right by one position) and converts them into dense vectors. Each token is mapped to a learnable embedding vector of a fixed size. The embedding vectors capture semantic and syntactic relationships between tokens.

Positional encoding 1101 is added to the output embedding 1130 to provide position information to the model. Positional encoding 1101 may be added to the output embedding 1130 through a function 1140. Since the Transformer architecture does not have inherent recurrence or convolution, positional encodings help capture the order and relative positions of tokens. The positional encodings are typically sine and cosine functions of different frequencies, allowing the model to learn relative positions.

The masked multi-head attention 1151 mechanism prevents the model form attending to future tokens. This layer performs self-attention on the Decoder's input sequence. It allows the Decoder to attend to different parts of its own input sequence. The attention is “masked” to prevent the Decoder from attending to future tokens, ensuring that the predictions are based only on the previously generated tokens. Multi-head attention splits the input into multiple heads, allowing the model to attend different aspect of the input simultaneously.

After the masked multi-head attention, a residual connection is applied follows by layer normalization via add and norm 1152. The residual connection adds the input to the output of the attention layer, helping the model learn faster and deeper. Layer normalization normalizes the activations across the features, stabilizing the training process.

The multi-head attention 1153 layer performs attention between the Decoder's hidden states and the Encoder's output. It allows the Decoder to attend to relevant parts of the input sequence based on the Encoder's representations. The attention weights are computed based on the compatibility between the Decoder's hidden states and Encoder's outputs.

Another add and norm 1154 layer is then followed by feed forward network 1155. This a fully connected feed-forward network applied to each position of the Decoder's hidden states. It consists of two linear transformations with a Rectified Linear Unit (ReLU) activation in between. The feed forward layer helps the model capture non-linear interactions and increases the model's capacity.

Another add and norm 1156 layer is followed by linear 1160 and softmax 1170 layers. The final hidden states of the Decoder are passed through a linear transformation to project them into the vocabulary space. Vocabulary space refers to the set of all unique tokens or words that the model can generate or predict. In the context of language models, the vocabulary is a predefined set of tokens that the model is trained on and can output. When the Decoder's final hidden states are passed through a linear transformation, they are projected into a vector space with the same dimensionality as the size of the vocabulary. Each dimension in this space corresponds to a specific token in the vocabulary. For example, the model has a vocabulary of 10,000 unique tokens. The linear transformation would project the Decoder's hidden states into a 10,000-dimensional vector space. Each element in this vector represents the model's predicted probability or score for the corresponding token in the vocabulary.

A softmax function is applied to the projected values (vectors) to generate output probabilities over the vocabulary. The softmax function normalizes the values so that they sum up to 1, representing a probability distribution over the vocabulary. Each probability indicates the likelihood of a specific token being the next output token. The token with the highest probability is selected as the next output token. During the model's training, the objective is to maximize the probability of the correct next token given the input sequence and the previously generated tokens. The model learns to assign higher probabilities to the tokens that are more likely to appear based on the context. At inference time, the token with the highest probability in the vocabulary space is selected as the next output token. This process is repeated iteratively, with the generated token being fed back into the Decoder as input for the next step, until a stopping criterion is met (e.g., reaching a maximum length or generating an end-of-sequence token). The size and composition of the vocabulary can vary depending on the specific task and the data the model is trained on. It can include words, sub-words, or even characters, depending on the tokenization strategy used.

The Decoder layers 1150 can be stacked Nx times, allowing the model to capture complex dependencies and generate coherent output sequences.

This transformer architecture allows the model to process input sequences, capture long-range dependencies, and generate output sequence based on the encoded input and the previously generated codewords.

There are at least three variations of transformer architecture that may enable an LCM. A first such variation comprises Auto-Encoding Models. In autoencoders, the decoder portion of the transformer is discarded after pre-training and only the encoder is used to generate the output. The popular BERT and RoBERTa models are examples of models based on this architecture and perform well on sentiment analysis and text classification. These types of models may be trained using a process called masked language modeling (MLM).

The primary goal of an autoencoder is to learn efficient representations of input data by encoding the data into a lower-dimensional space and then reconstructing the original data from the encoded representation. Autoencoders are trained in an unsupervised manner, meaning they don't require labeled data. They learn to capture the underlying structure and patterns in the input data without explicit guidance. An autoencoder consists of two main components: an encoder and a decoder. The encoder takes the input data and maps it to a lower-dimensional representation, often referred to as the latent space or bottleneck. The decoder takes the latent representation and tries to reconstruct the original input data. Autoencoders can be used for dimensionality reduction by learning a compressed representation of the input data in the latent space. The latent space has a lower dimensionality than the input data, capturing the most salient features or patterns. The training objective of an autoencoder is to minimize the reconstruction error between the original input and the reconstructed output. The model learns to encode and decode the data in a way that preserves the essential information needed for reconstruction. Variants and extensions of autoencoders can include denoising autoencoders, variational autoencoders (VAEs) which introduce a probabilistic approach to autoencoders wherein they learn a probabilistic encoder and decoder, allowing for generating new samples from the learned latent space, and conditional autoencoders which incorporate additional conditions or labels as input to the encoder and decoder, enabling the generation of samples conditioned on specific attributes.

Autoencoders can have various applications. Autoencoders can be used to detect anomalies by measuring the reconstruction error. Anomalous samples tend to have higher reconstruction errors compared to normal samples. Autoencoders can be used as a pre-training step to learn meaningful features from unlabeled data. The learned features can then be used for downstream tasks like classification or clustering. Additionally, or alternatively, autoencoders, particularly VAEs, can be used as generative models to generate new samples similar to the training data by sampling from the learned latent space. It's worth noting that while autoencoders can be effective for certain tasks, they have some limitations. They may struggle to capture complex dependencies and may generate blurry or less sharp reconstructions compared to other generative models like Generative Adversarial Networks (GANs).

Another type of variation is the auto-regressive model which feature the use of only the decoder portion of the transformer architecture. In autoregressive architectures, the decoder portion of the transformer is retained and the encoder portion is not used after model pre-training. Auto-regressive models are a class of models that generate outputs by predicting the next element based on the previously generated elements. In the context of the Transformer architecture and language modeling, auto-regressive models are commonly used for tasks such as text generation, machine translation, and language understanding.

Auto-regressive models generate outputs sequentially, one element at a time. In the case of language modeling, the model predicts the next word or token based on the previous words or tokens in the sequence. The prediction of the next element is conditioned on the previously generated elements. The model learns the conditional probability distribution P(x_t|x_1, x_2, . . . , x_{t−1}), where x_t is the element at position t, and x_1, x_2, . . . , x_{t−1} are the previously generated elements. The Transformer architecture, particularly the Decoder component, is well-suited for auto-regressive modeling. The Decoder generates the output sequence one element at a time, conditioned on the previously generated elements and the encoded input sequence from the Encoder. In the Transformer Decoder, the self-attention mechanism is masked to prevent the model from attending to future positions during training. This masking ensures that the model relies only on the previously generated elements to make predictions, following the auto-regressive property. During training, the Transformer Decoder uses a technique called teacher forcing. Instead of feeding the model's own predictions as input for the next step, the ground truth target sequence is used. This helps the model learn to generate the correct output sequence based on the input sequence and the previous target tokens. During inference or generation, the Transformer Decoder generates the output sequence one element at a time. At each step, the model takes the previously generated elements as input and predicts the next element. This process continues until a stopping criterion is met, such as reaching a maximum sequence length or generating an end-of-sequence token. Auto-regressive models, including the Transformer, have achieved state-of-the-art performance in language modeling tasks. They excel at capturing the statistical properties and dependencies in sequential data, making them effective for generating coherent and fluent text.

While text generation is the most suitable use case of auto-regressors, they perform exceptionally well on a wide variety of tasks. Most modern LLMs are auto-regressors including, for example, the popular GPT series of LLMs, BERT, and XLNet.

The third variation of the transformer model is the sequence-to-sequence model which utilizes both the encoder and decoder portions of the transformer and can be trained in multiple ways. One of the methods is span corruption and reconstruction. These models are, generally, best suited for language translation. The T5 and BART family of models are examples of sequence-to-sequence models.

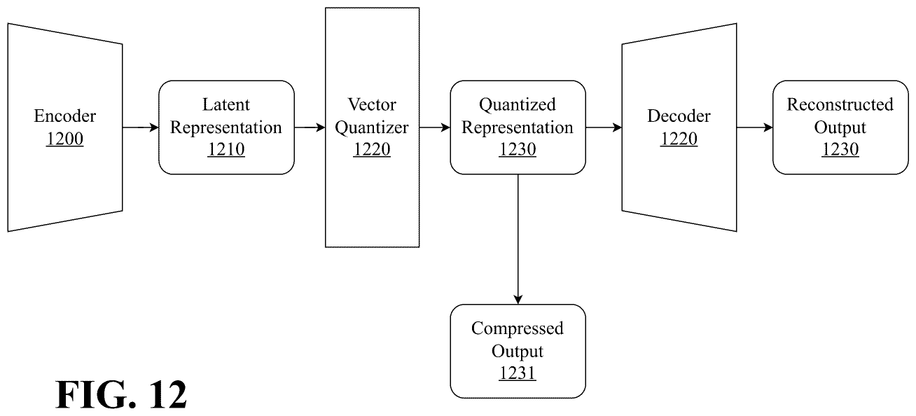

FIG. 12 is a block diagram illustrating an exemplary architecture for a subsystem of a system for federated two-stage compression with federated joint learning, a Variatitional Autoencoder with Vector Quantization (VAE-VQ) based compression network. The system begins with an encoder 1200, which is a key component of the Variational Autoencoder VAE architecture. The encoder takes input data and maps it to a latent representation 1210. In a VAE, this latent representation is generally not a single point in the latent space, but rather a probability distribution, typically modeled as a multivariate Gaussian. This probabilistic approach allows the VAE to capture uncertainty and variability in the input data, leading to more robust and generalizable representations.

The latent representation 1210 is then passed to the vector quantizer 1220. Vector Quantization (VQ) is a technique that maps continuous vectors to a finite set of discrete vectors, called a codebook. The vector quantizer compares the input latent representation to each vector in its codebook and selects the closest match. This process effectively discretizes the continuous latent space, creating a quantized representation 1230. The use of VQ introduces a form of lossy compression, as the continuous input is mapped to a finite set of discrete values.

The quantized representation 1230 serves two purposes in this system. First, it is used as the compressed output 1231, which can be efficiently stored or transmitted. This compressed form significantly reduces the data size while preserving the most important features of the original input.

Secondly, the quantized representation 1230 may be fed into a decoder 1220. The decoder, another component of the VAE architecture, is trained to reconstruct the original input data from the latent representation. In this case, it works with the quantized version of the latent representation. The decoder outputs a reconstructed output 1230, which aims to closely match the original input data.

The VAE-VQ system is trained end-to-end to minimize two main types of loss: reconstruction loss, which measures how closely the reconstructed output matches the original input, and a commitment loss, which encourages the encoder to produce latent representations that can be accurately quantized. Additionally, the vector quantizer's codebook may updated during training to better represent the distribution of the latent space.

This combination of VAE and VQ offers several advantages. The VAE component allows for learning of meaningful, continuous latent representations that capture the underlying structure of the data. The VQ component then provides a way to discretize this continuous space, enabling more efficient compression. Together, they create a powerful system for generating compact, information-rich representations of complex data, making it particularly useful for applications in data compression, feature learning, and generative modeling.

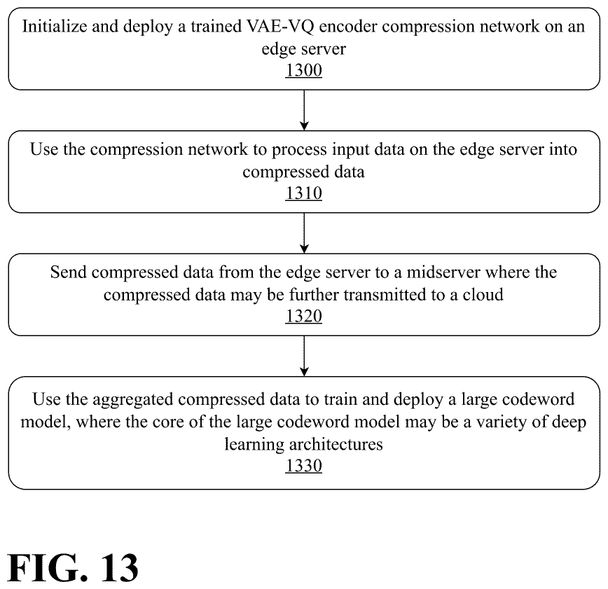

FIG. 13 is a flow diagram illustrating an exemplary method for federated two-state compression with federated joint learning using a VAE-VQ and a transformer. In a first step 1300, a trained VAE-VQ encoder compression network is initialized and deployed on an edge server. This step involves setting up a sophisticated compression network that combines a Variational Autoencoder (VAE) with Vector Quantization (VQ). The VAE component learns to encode input data into a meaningful latent space representation, while the VQ component discretizes this representation for more efficient compression. This network is pre-trained on relevant data to ensure it can effectively compress the specific types of input the edge server will encounter.

In a step 1310, the compression network is used to process input data on the edge server into compressed data. This step involves feeding raw input data through the VAE-VQ network. The encoder part of the VAE maps the input to a latent representation, which is then quantized by the VQ component. This process significantly reduces the data size while preserving essential features and structure of the original input. The resulting compressed data is a compact, discrete representation of the original input, suitable for efficient storage or transmission.

In a step 1320, the compressed data is sent from the edge server to a midserver where it may be further transmitted to a cloud. This step facilitates the movement of compressed data through the system's hierarchy. The midserver acts as an intermediary, potentially performing additional processing or aggregation of data from multiple edge servers before forwarding it to the cloud. This multi-tier approach allows for efficient data handling and reduces the bandwidth required between the edge and the cloud.

In a step 1330, the aggregated compressed data is used to train and deploy a large codeword model, where the core of the large codeword model may be a variety of deep learning architectures. This step takes place in the cloud environment, leveraging its superior computational resources. The compressed data from multiple sources is aggregated and used to train a sophisticated model that can understand and generate these compressed representations. The core of this model could be implemented using various architectures, such as Transformers, which excel at processing sequential data and capturing long-range dependencies; Diffusion models, which have shown promise in generative tasks; or other custom deep learning architectures tailored to the specific requirements of the system. This large codeword model serves as the central intelligence of the system, capable of performing complex tasks or generating outputs based on the compressed input data.

This method outlines a powerful approach to distributed, efficient data processing and model training. It leverages edge computing for initial data compression, uses midservers for data aggregation and transmission, and employs cloud resources for sophisticated model training and deployment. This hierarchical structure allows for efficient use of resources at each level while enabling the development of powerful, data-driven models.

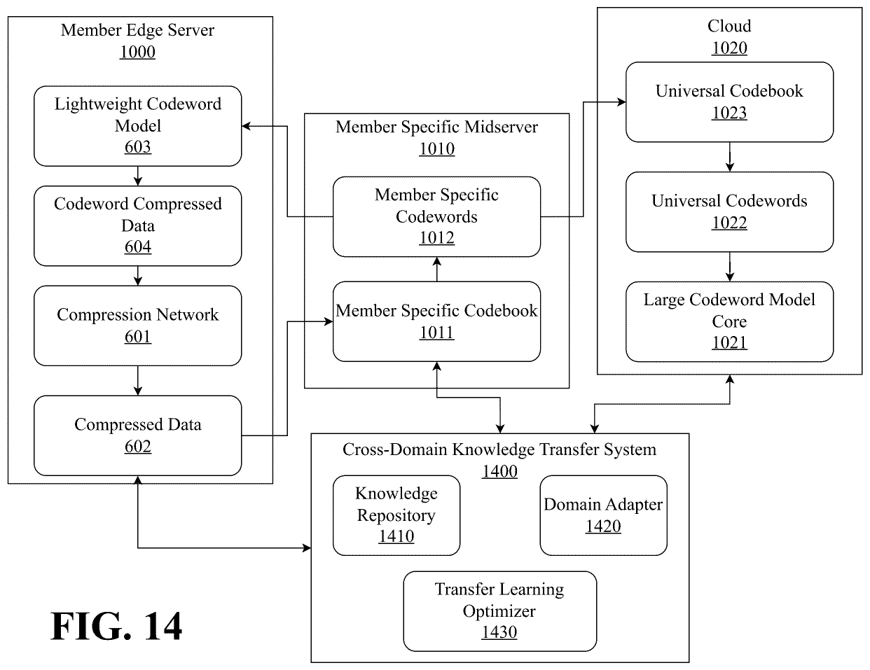

FIG. 14 is a block diagram illustrating an exemplary system architecture for a system for federated two-stage compression with federated joint learning that incorporates a cross-domain knowledge transfer system. In one embodiment, the system includes the addition of a cross-domain knowledge transfer system 1400 fundamentally transforms how knowledge flows through the system and how compression strategies evolve across different data domains.

The cross-domain knowledge transfer system 1400 addresses the inability to effectively leverage knowledge across different data domains. In conventional federated systems, a compression network trained on one type of data (such as text) would need to be completely retrained when faced with a different type of data (such as images or sensor readings). This leads to significant inefficiencies, as each domain essentially starts from scratch despite potential similarities in underlying patterns or compression principles. The cross-domain knowledge transfer system 1400 overcomes this limitation through a knowledge repository 1410, a domain adapter 1420, and a transfer learning optimizer 1430.

Knowledge repository 1410 functions as the system's collective memory, storing and organizing compression patterns, strategies, and domain-specific features discovered during operation. Knowledge repository 1410 employs indexing and retrieval mechanisms that associate compression strategies with domain characteristics. For example, when processing satellite imagery data, the system might discover that a particular compression strategy works exceptionally well for cloud formations. Knowledge repository 1410 stores not just the compression parameters, but also the contextual information about when and why these parameters perform well. This contextual binding enables more intelligent retrieval and adaptation later.

Knowledge repository 1410 continuously evolves through operation, with new patterns being added, existing patterns being refined, and obsolete patterns being pruned based on performance metrics. Knowledge repository 1410 is capable of implementing versioning to track the evolution of compression strategies over time, enabling rollback if needed and providing insights into the development trajectory of different strategies. Additionally, knowledge repository 1410 may employ hierarchical organization to capture relationships between different domains and subdomains, creating a taxonomy of compression knowledge that facilitates efficient knowledge transfer.

For instance, in a smart city application, data from traffic cameras, environmental sensors, and utility meters would all be processed through the system. Knowledge repository 1410 would identify that while these data sources differ in many ways, they share certain temporal patterns related to human activity cycles. This common characteristic would be stored alongside domain-specific compression strategies, enabling cross-domain transfer when appropriate.

Domain adapter 1420 serves as the intelligence layer that analyzes and classifies incoming data streams, identifies similarities with known domains, and determines how existing compression knowledge should be adapted to new contexts. Domain adapter 1420 employs machine learning techniques to extract feature representations from incoming data and compare these representations against the domain characteristics stored in the knowledge repository.

When processing a new data stream, domain adapter 1420 first performs feature extraction to identify key characteristics such as statistical distributions, temporal patterns, spatial relationships, or spectral properties. It then compares these features against known domains using similarity metrics such as cosine similarity, Jensen-Shannon divergence, or mutual information. Based on this analysis, the domain adapter identifies the most similar existing domains and retrieves relevant compression strategies from the knowledge repository.

Domain adapter 1420 does not merely select the closest matching domain but performs a more nuanced analysis that considers partial similarities across multiple domains. For example, when facing a new type of medical imaging data, domain adapter 1420 might recognize spatial structure similarities with natural images and value distribution similarities with other medical data, creating a composite adaptation strategy that leverages both sources of knowledge.

Domain adapter 1420 may employs active learning techniques to continuously refine its domain representation. When it encounters data that doesn't closely match any known domain, it flags this data for special attention and initiates the creation of a new domain category in the knowledge repository. This ensures that the system's knowledge taxonomy expands organically as it encounters new types of data.

The transfer learning optimizer 1430 implements the actual mechanisms for transferring and adapting knowledge between domains. While the domain adapter identifies what knowledge should be transferred, the transfer learning optimizer determines how this transfer should occur at the parameter and algorithm level.

Transfer learning optimizer 1430 employs a diverse set of techniques to facilitate effective knowledge transfer. It uses neural network weight transformation algorithms to map parameters from source domains to target domains, accounting for differences in data distributions and feature spaces. These transformations may involve scaling, regularization, or more complex operations that preserve the essential knowledge while adapting to new contexts.

Optimizer 1430 also implements gradient-based transfer methods that align optimization trajectories between source and target domains. This ensures that the learning process in the new domain benefits from the optimization path discovered in the source domain, even when the specific parameters differ. For example, when transferring knowledge from text to audio compression, the gradient alignment might preserve the learning trajectory for sequence modeling while adapting to the different feature distributions.

Meta-learning capabilities within transfer learning optimizer 1430 enable the system to “learn how to learn” across domains. Optimizer 1430 identifies and captures higher-order patterns in how compression networks adapt to different domains, creating meta-models that can rapidly configure new compression networks with minimal data. This meta-learning approach is particularly valuable for zero-shot or few-shot learning scenarios, where a new domain must be addressed with very limited examples.

Transfer learning optimizer 1430 may also implement feedback mechanisms that evaluate the effectiveness of knowledge transfer and adjust strategies accordingly. When a transfer proves particularly successful, the optimizer reinforces this pathway in future operations. Conversely, when a transfer performs poorly, the optimizer modifies its approach and explores alternative transfer strategies. This continuous feedback loop ensures that the transfer learning process itself improves over time.

In operation, the cross-domain knowledge transfer system 1400 maintains bidirectional connections with all three primary components of the federated architecture. These connections enable a flow of information and knowledge throughout the system:

From member edge server 1000, cross-domain knowledge transfer 1400 system receives compressed data 602 and performance metrics from compression network 601. It analyzes this information to identify domain characteristics and successful compression patterns. In return, it provides adapted compression strategies that enhance the performance of the compression network for specific data types.

With member specific midserver 1010, cross-domain knowledge transfer system 1400 exchanges codebook optimization strategies. It enhances member specific codebook 1011 by incorporating knowledge about codeword distributions and relationships from similar domains. This cross-domain knowledge helps the codebook more effectively represent the compressed data, even when facing new data types.

At the cloud level 1020, cross-domain knowledge transfer system 1400 interfaces with the large codeword model core 1021, providing insights about domain relationships that enhance the model's generalization capabilities. The universal codebook 1023 is similarly enhanced with cross-domain knowledge about codeword relationships, improving its effectiveness across diverse data types.

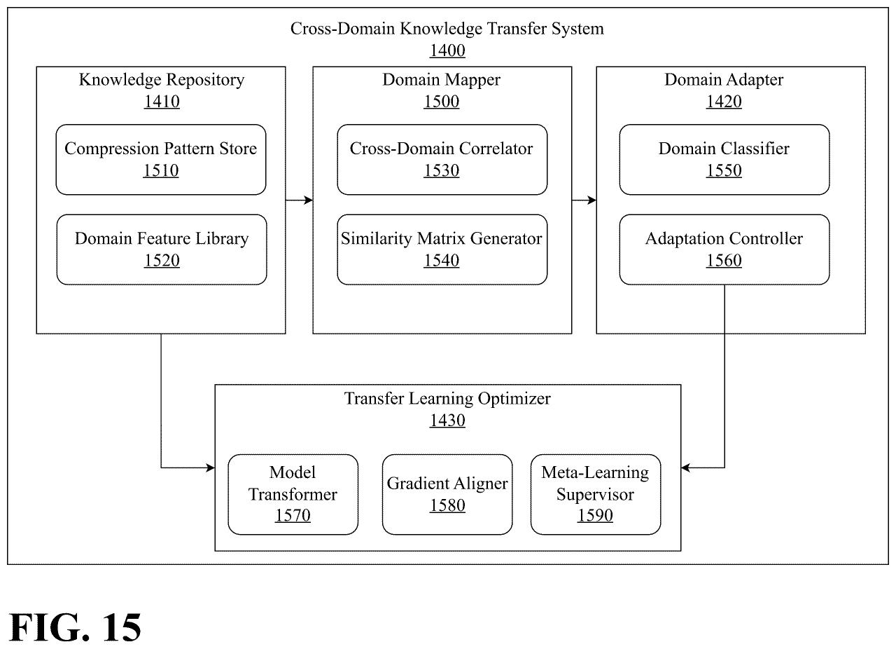

FIG. 15 is a block diagram illustrating the detailed internal architecture of a cross-domain knowledge transfer system. Cross-domain knowledge transfer system 1400 employs a modular architecture with specialized components that work together to identify, store, adapt, and optimize knowledge transfer between different data domains. This architecture enables the system to overcome the traditional limitations of domain-specific compression systems by facilitating intelligent sharing of compression strategies across diverse data types.

Knowledge repository 1410 forms the foundation of the system's cross-domain capabilities through two specialized sub-components. A compression pattern store 1510 implements a database architecture that captures and organizes successful compression strategies discovered across various data domains. Unlike traditional model storage systems that simply save parameter values, the compression pattern store employs a metadata model that links compression parameters with contextual information about when, where, and why these parameters perform well. This store captures compression strategies at multiple levels of abstraction, from low-level network weights to high-level architectural patterns.

For example, when processing financial time-series data, compression pattern store 1510 might discover that a specific configuration of attention mechanisms efficiently captures seasonal patterns while preserving anomalies. This pattern would be stored with metadata identifying the data characteristics that make this strategy effective, such as periodicity, sparsity of significant events, and value distribution properties. The pattern store implements indexing mechanisms using multi-dimensional feature vectors that enable efficient retrieval based on domain similarity rather than explicit domain categorization.

A domain feature library 1520 complements the compression pattern store by maintaining characteristic features of different data domains. This library stores domain fingerprints—distinctive feature vectors that capture the essential characteristics of different data types. These fingerprints are extracted through a combination of statistical analysis, information theory metrics, and learned representations. For instance, the domain fingerprint for satellite imagery data might include spatial autocorrelation metrics, frequency domain characteristics, and distributional statistics that distinguish it from other image types.

Domain feature library 1520 may employ hierarchical organization to capture relationships between domains and subdomains. For example, it might recognize that medical imaging forms a broader domain with subdomain distinctions between MRI, CT, and ultrasound data, each with their own characteristic features while sharing certain higher-level properties. This hierarchical structure facilitates more nuanced knowledge transfer by identifying partial matches at different levels of abstraction.

A domain mapper 1500 serves as the analytical engine that identifies relationships between different data domains through two sub-components. A cross-domain correlator 1530 implements advanced correlation techniques to discover non-obvious relationships between different data domains. Unlike simple similarity metrics, the correlator employs techniques such as canonical correlation analysis, transfer entropy measurement, and deep correlation learning to identify meaningful connections between seemingly disparate data types.

For example, cross-domain correlator 1530 might discover that vibration sensor data from industrial equipment shares certain temporal pattern properties with audio data, despite the domains appearing unrelated on the surface. This discovery would enable transfer of certain compression strategies between these domains. The correlator continuously analyzes new domain pairs to expand the system's understanding of cross-domain relationships.

A similarity matrix generator 1540 transforms the correlations identified by the cross-domain correlator into structured mathematical representations that guide knowledge transfer. These similarity matrices are multi-dimensional tensors that quantify domain relationships across various feature dimensions. Each element in a similarity matrix represents the strength of relationship between domains along a specific characteristic, such as temporal structure, value distribution, or information density.

These matrices provide a mathematical foundation for determining which aspects of compression knowledge are most transferable between domains. For instance, a similarity matrix might indicate that satellite imagery and medical imaging share high similarity in spatial structure (0.85) but low similarity in value distributions (0.23), guiding how spatial compression techniques might be transferred while adapting to different value characteristics.

Domain adapter 1420 translates the domain relationships identified by the domain mapper into practical adaptation strategies through two specialized sub-components. Domain classifier 1550 implements a multi-model classification system that categorizes incoming data streams into known domains or identifies them as requiring new domain definitions. Unlike simple classifiers that assign a single category, this classifier generates confidence scores across multiple potential domains, enabling nuanced adaptation strategies for data that exhibits characteristics of multiple domains.

Classifier 1550 may employ a combination of unsupervised clustering, supervised classification, and novelty detection algorithms to provide domain identification even for previously unseen data types. For example, when presented with a new type of sensor data, the classifier might determine that it shares characteristics with both audio data (0.7 confidence) and seismic data (0.5 confidence), enabling adaptation strategies that draw from both domains.

An adaptation controller 1560 uses the domain classification along with similarity matrices to orchestrate the actual adaptation of compression strategies between domains. This controller implements a decision system that determines which aspects of source domain knowledge should be preserved, which should be modified, and which should be discarded when transferring to a target domain. Controller 1560 generates adaptation plans that specify transformations at multiple levels, from low-level parameter adjustments to high-level architectural modifications.

For instance, when adapting knowledge from natural image compression to medical image compression, the adaptation controller might preserve convolutional structures that capture spatial relationships while modifying activation functions and normalization layers to account for different value distributions and contrast characteristics. The controller employs reinforcement learning techniques to continuously refine its adaptation strategies based on performance feedback.

Transfer learning optimizer 1430 implements the core mechanisms for efficient knowledge transfer through three specialized sub-components. A model transformer 1570 executes the parameter-level transformations specified by the adaptation controller. This transformer employs a diverse set of techniques including weight transformation matrices, architectural surgery, and representation alignment to effectively transfer model parameters between domains while preserving essential knowledge.

Model transformer 1570 implements neural network surgery algorithms that can modify network architectures while preserving functional relationships. For example, when transferring from a compression network optimized for dense text to one for sparse sensor data, the model transformer might remove certain dense layers while preserving pattern recognition capabilities, or insert attention mechanisms optimized for the temporal characteristics of the target domain.

A gradient aligner 1580 addresses the challenges of optimization dynamics that differ between domains. When transferring knowledge, simply copying model parameters often results in poor optimization trajectories in the new domain. Gradient aligner 1580 implements techniques such as gradient surgery, optimization landscape mapping, and curvature matching to ensure that optimization proceeds effectively despite domain differences.

For instance, when transferring from image to audio compression, the optimization landscape might differ significantly due to different feature distributions. The gradient aligner would apply transformations to gradients during training to align optimization trajectories, ensuring that the learning process in the audio domain benefits from knowledge gained in the image domain without being derailed by domain-specific optimization challenges.

A meta-learning supervisor 1590 implements advanced meta-learning algorithms that enable rapid adaptation to new domains with minimal data. This supervisor doesn't just transfer specific model parameters but captures higher-order knowledge about how compression networks adapt to different domains. It implements techniques such as model-agnostic meta-learning, prototypical networks, and optimization-based meta-learning to create “learning to learn” capabilities across domains.

For example, the meta-learning supervisor might discover that certain types of initialization strategies consistently lead to faster convergence across various time-series data types. When a new time-series domain is encountered, the supervisor would apply this meta-knowledge to accelerate adaptation, even with limited examples. The supervisor maintains a meta-model that continuously evolves as it observes adaptation across more domain pairs.

In operation, these components work together in a workflow that enables efficient knowledge transfer between domains. The knowledge flow typically follows this sequence: knowledge repository 1410 provides domain features and compression patterns to domain mapper 1500, which analyzes these inputs to identify correlations and generate similarity matrices. These matrices inform domain adapter 1420, which classifies incoming data and determines appropriate adaptation strategies. Domain adapter then directs transfer learning optimizer 1430 to execute specific transformations that enable effective knowledge transfer.

This process is not merely sequential but involves feedback loops and parallel operations. As the system processes more diverse data, it continuously refines its understanding of domain relationships and adaptation strategies. Performance metrics from adapted compression networks flow back to update the knowledge repository, improving future transfer operations. The domain mapper periodically reanalyzes the expanding domain feature library to discover new cross-domain relationships. The meta-learning supervisor observes the outcomes of transfer operations to refine its meta-knowledge about effective adaptation strategies.

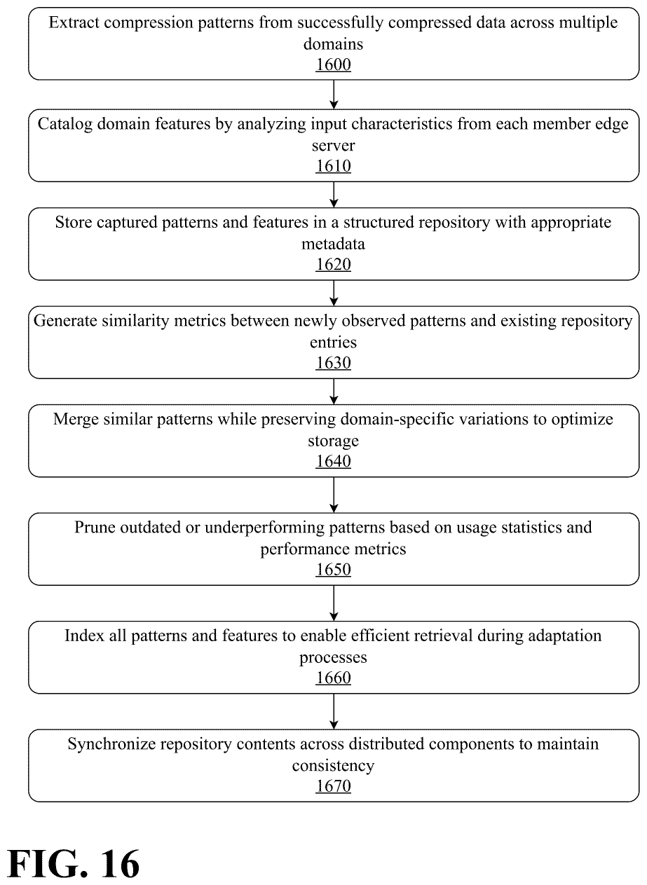

FIG. 16 is a flow diagram illustrating an exemplary method for cross-domain knowledge acquisition and repository management within the federated two-stage compression system. This method enables the systematic collection, organization, and maintenance of compression knowledge across diverse data domains, forming the foundation for effective cross-domain knowledge transfer.

In a first step 1600, extract compression patterns from successfully compressed data across multiple domains. This step involves analyzing the performance of compression networks operating on different types of data to identify effective compression strategies. The system monitors compression networks during operation, capturing parameter configurations, architectural patterns, and optimization trajectories that yield high compression ratios with minimal information loss. These patterns are extracted at multiple levels of abstraction, from low-level network weights to high-level architectural principles.

In a step 1610, catalog domain features by analyzing input characteristics from each member edge server. This step involves developing comprehensive fingerprints of different data domains based on their statistical, structural, and semantic properties. The system applies a battery of analysis techniques to characterize each domain, including statistical distribution analysis, information-theoretic measures, frequency domain analysis, and learned feature representations.

For instance, when analyzing financial time-series data, the system might extract features related to periodicity, volatility clustering, and long-range dependencies. For image data, it might extract features related to spatial autocorrelation, edge density, and spectral characteristics. These domain features serve as the context in which compression patterns operate, enabling the system to understand when and why specific compression strategies are effective.

In a step 1620, store captured patterns and features in a structured repository with appropriate metadata. This step involves organizing the extracted compression patterns and domain features into a knowledge repository with rich contextual information. The repository employs a data model that links compression patterns with the domain features for which they are effective, creating a multidimensional knowledge space.

Each stored pattern includes metadata such as the source domain, performance metrics, resource requirements, and compatibility constraints. This metadata enables intelligent retrieval and adaptation of patterns based on context. The repository structure supports multiple abstraction levels, from concrete parameter values to general architectural principles, facilitating knowledge transfer at the appropriate level for different scenarios. The system employs versioning mechanisms to track the evolution of patterns over time, maintaining historical context that informs future adaptations.

In a step 1630, generate similarity metrics between newly observed patterns and existing repository entries. This step involves computing mathematical measures of similarity between compression patterns and domain features to identify potential knowledge transfer opportunities. The system employs a diverse set of similarity metrics tailored to different aspects of compression knowledge, including parameter space similarity, functional similarity, and performance profile similarity.

For parameter space similarity, the system might compute cosine similarity between weight vectors or Frobenius norms between weight matrices. For functional similarity, it might analyze the response characteristics of different network components to similar inputs. For performance profile similarity, it might compare compression ratio and quality trade-off curves across different datasets. These multifaceted similarity metrics enable the system to identify non-obvious relationships between compression strategies that might not be apparent from surface-level comparison.

In a step 1640, merge similar patterns while preserving domain-specific variations to optimize storage. This step involves consolidating redundant knowledge in the repository while maintaining important domain-specific nuances. The system identifies patterns that share fundamental principles but differ in specific parameter values or architectural details due to domain differences.

Rather than storing these as entirely separate patterns, the system creates generalized templates with parameterized variations that capture domain-specific adaptations. For example, if two convolutional filter patterns share the same essential structure but differ in scale parameters due to differences in input resolution, the system would store a single template pattern with resolution-dependent scaling factors. This approach significantly reduces storage requirements while preserving the adaptability of the knowledge for different domains.

In a step 1650, prune outdated or underperforming patterns based on usage statistics and performance metrics. This step involves maintaining the quality and relevance of the knowledge repository through systematic curation. The system tracks usage statistics for each pattern, including frequency of retrieval, success rate when applied to new domains, and performance improvements achieved through adaptation.

Patterns that consistently underperform relative to alternatives, or that have been superseded by newer strategies, are flagged for pruning. The pruning process involves either complete removal or archival to secondary storage, depending on the pattern's historical significance. This continuous refinement ensures that the repository remains focused on the most effective and relevant compression knowledge, improving retrieval efficiency and adaptation quality.

In a step 1660, index all patterns and features to enable efficient retrieval during adaptation processes. This step involves creating optimized data structures that facilitate rapid identification of relevant compression knowledge when adapting to new domains. The system implements multidimensional indexing schemes that support similarity-based queries across various feature dimensions.

These indices enable the system to quickly identify patterns that match specific domain characteristics or performance requirements. For example, when adapting to a new type of sensor data, the system can efficiently retrieve compression patterns that have proven effective for data with similar statistical distributions and temporal characteristics. The indexing strategies balance query speed with flexibility, supporting both exact matches and similarity-based retrieval.

In a step 1670, synchronize repository contents across distributed components to maintain consistency. This step involves ensuring that all components of the federated system have access to the same compression knowledge, despite their distributed nature. The system implements synchronization protocols that efficiently propagate knowledge updates throughout the network while minimizing bandwidth usage.

These protocols employ incremental updates that transmit only changed knowledge components, version reconciliation mechanisms that resolve conflicts when different components have made parallel updates, and priority-based synchronization that ensures critical knowledge is propagated first. This synchronization process ensures that all edge servers, midservers, and cloud components operate with a consistent knowledge base, enabling coherent cross-domain adaptation throughout the federated system.

Through this comprehensive method for knowledge acquisition and repository management, the cross-domain knowledge transfer system builds and maintains a rich foundation of compression knowledge spanning diverse domains. This knowledge repository powers the adaptation and optimization processes that enable efficient knowledge transfer, significantly enhancing the performance, efficiency, and adaptability of the federated two-stage compression system across diverse applications and data types.

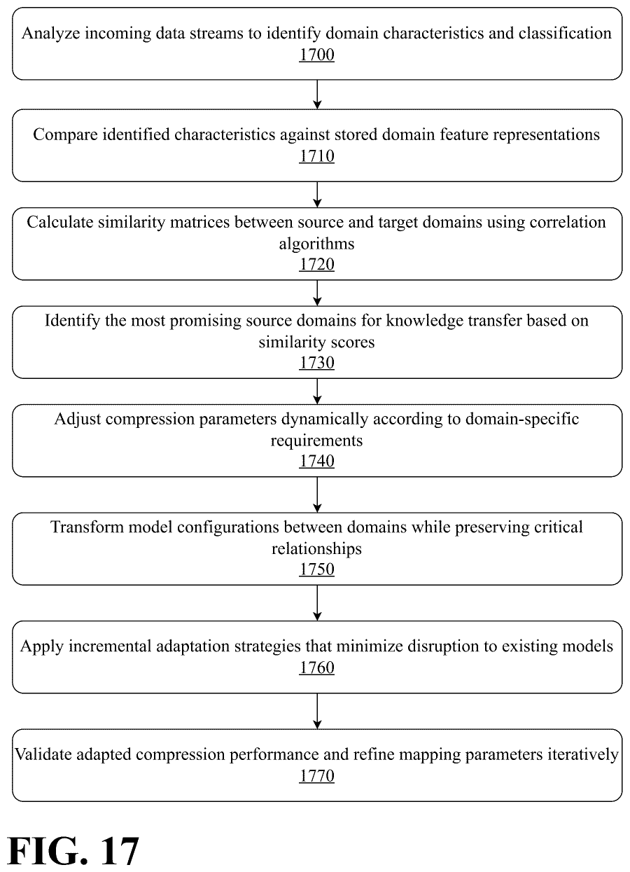

FIG. 17 is a flow diagram illustrating an exemplary method for domain mapping and adaptation within the federated two-stage compression system. This method enables the intelligent identification of relationships between different data domains and the systematic adaptation of compression strategies across these domains, forming the core operational process of the cross-domain knowledge transfer system.

In a first step 1700, analyze incoming data streams to identify domain characteristics and classification. This step involves the application of feature extraction and analysis techniques to characterize new data entering the system. When a data stream arrives at a member edge server, the system applies a comprehensive suite of analytical methods to extract its essential characteristics, including statistical distribution analysis, temporal or spatial pattern recognition, information density measurement, and frequency domain analysis.

For instance, when analyzing a stream of sensor data from industrial equipment, the system might extract features related to sampling frequency, noise characteristics, periodicity, and signal dynamics. These extracted features form a multidimensional representation of the data domain that serves as its fingerprint. The system then employs classification algorithms to associate this fingerprint with known domain categories or to identify it as a novel domain requiring special handling. The classification process generates confidence scores across multiple potential domain categories, enabling nuanced domain identification even for data that exhibits characteristics of multiple domains.

In a step 1710, compare identified characteristics against stored domain feature representations. This step involves matching the features extracted from incoming data against the domain fingerprints stored in the knowledge repository. The system employs matching algorithms that account for variations in feature importance and allow for partial matches across different feature dimensions.

Rather than seeking exact matches, which are rare when dealing with diverse real-world data, the system quantifies similarity along multiple dimensions of comparison. For example, when comparing a new type of medical imaging data to stored domain representations, the system might find high similarity with existing medical images in terms of value distribution and noise characteristics, but lower similarity in spatial structure. These multidimensional comparisons provide the foundation for identifying potential knowledge transfer sources, even when no exact domain match exists.

In a step 1720, calculate similarity matrices between source and target domains using correlation algorithms. This step involves the generation of structured mathematical representations of domain relationships that will guide the knowledge transfer process. The system constructs similarity matrices that quantify the relationship between domains across various feature dimensions using advanced correlation techniques such as canonical correlation analysis, mutual information estimation, and dynamic time warping for sequential data.

These matrices capture nuanced relationships that might not be apparent from simple feature comparison. For example, a similarity matrix might reveal that while financial time-series data and network traffic data appear different superficially, they share important structural similarities in how anomalies manifest and propagate. The matrices are multi-dimensional tensors, with each dimension corresponding to a different aspect of domain comparison, such as statistical properties, temporal dynamics, or information content. These rich representations enable targeted knowledge transfer that preserves relevant aspects of compression strategies while adapting to domain differences.

In a step 1730, identify the most promising source domains for knowledge transfer based on similarity scores. This step involves the strategic selection of knowledge sources that are most likely to provide transferable compression strategies for the target domain. Rather than simply selecting the single most similar domain, the system conducts an analysis that considers partial similarities across multiple domains and the specific compression requirements of the target application.

The selection process employs a combination of similarity thresholding, weighted scoring across feature dimensions, and historical performance analysis of previous transfers between similar domain pairs. For instance, when adapting to a new type of financial data, the system might identify that certain aspects of text compression strategies are surprisingly effective for capturing patterns in numerical sequences, despite the domains appearing unrelated on the surface. This step results in a prioritized list of source domains, often including multiple candidates that offer complementary knowledge for different aspects of the target domain.

In a step 1740, adjust compression parameters dynamically according to domain-specific requirements. This step involves the fine-tuning of compression strategies to address the particular characteristics and quality requirements of the target domain. The system employs a parameter adaptation framework that systematically maps parameters from source domains to appropriate values for the target domain, accounting for differences in data distributions, noise levels, and information density.

The adaptation process considers both general principles derived from similarity analysis and specific requirements such as minimum quality thresholds or maximum latency constraints. For example, when adapting video compression strategies to medical imaging, the system might preserve the spatial compression approach while adjusting quality parameters to ensure diagnostic features are preserved with higher fidelity than would be necessary for entertainment content. This dynamic parameter adjustment enables the transferred compression strategies to meet domain-specific requirements without requiring complete retraining.

In a step 1750, transform model configurations between domains while preserving critical relationships. This step involves the structural adaptation of compression models to account for fundamental differences between source and target domains. Beyond simple parameter adjustment, this transformation may involve architectural modifications, representation changes, or computational pipeline adjustments that preserve the essential knowledge while adapting to domain-specific characteristics.

The transformation process employs neural network surgery techniques that can modify network architectures while preserving functional relationships, representation alignment methods that map between different feature spaces, and initialization strategies that leverage source domain knowledge effectively. For instance, when transferring from image to audio compression, the transformation might convert 2D convolutional structures to 1D equivalents that operate on spectrograms, preserving pattern recognition capabilities while adapting to the different data structure. These transformations enable the preservation of valuable compression principles across significantly different domains.

In a step 1760, apply incremental adaptation strategies that minimize disruption to existing models. This step involves the careful integration of adapted knowledge into operational compression systems without compromising their existing capabilities. Rather than replacing entire models, which could disrupt performance on well-established tasks, the system employs incremental adaptation techniques that gradually incorporate new knowledge while maintaining stability.

These techniques include progressive fine-tuning with stability constraints, knowledge distillation from source to target models, and modular component replacement that preserves critical functionality. For example, when adapting a compression network that handles multiple data types, the system might modify only the components specific to the new domain while preserving shared components that perform well across domains. This incremental approach ensures that the integration of cross-domain knowledge enhances rather than disrupts the overall system performance.

In a step 1770, validate adapted compression performance and refine mapping parameters iteratively. This step involves the systematic evaluation and improvement of adapted compression strategies to ensure they meet performance requirements. The system implements a comprehensive validation framework that assesses multiple aspects of compression performance, including compression ratio, quality preservation, computational efficiency, and generalization to varied data within the target domain.

Based on validation results, the system refines the mapping parameters that guide knowledge transfer, adjusting similarity weightings, transformation rules, or adaptation strategies to improve performance. This refinement process employs techniques such as Bayesian optimization, reinforcement learning, or evolutionary algorithms to efficiently explore the adaptation parameter space. For instance, if validation reveals that certain features are being over-compressed in the target domain, the system might adjust the weightings of quality preservation terms in the adaptation parameters. This iterative refinement creates a feedback loop that continuously improves the effectiveness of cross-domain knowledge transfer.

Through this comprehensive method for domain mapping and adaptation, the cross-domain knowledge transfer system enables efficient knowledge sharing across diverse data domains. This capability significantly enhances the performance, efficiency, and adaptability of the federated two-stage compression system by allowing new domains to leverage compression knowledge from related domains rather than developing compression strategies from scratch. The method ensures that valuable compression principles are preserved while appropriately adapting to the specific characteristics and requirements of each domain, creating a knowledge ecosystem that continuously evolves and improves across the entire federated architecture.

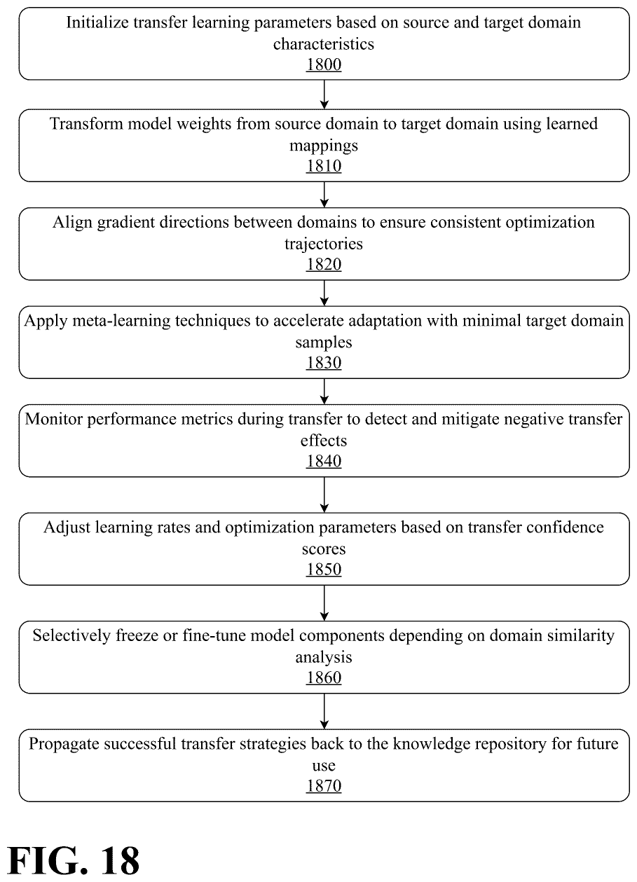

FIG. 18 is a flow diagram illustrating an exemplary method for transfer learning optimization within the federated two-stage compression system. This method enables the efficient and effective transfer of compression knowledge between different data domains by optimizing the learning process itself, serving as the performance engine of the cross-domain knowledge transfer system.

In a first step 1800, initialize transfer learning parameters based on source and target domain characteristics. This step involves configuring the learning process specifically for the domain transfer task at hand, using insights from the domain mapping analysis. The system establishes a comprehensive set of transfer parameters that govern how knowledge will flow between domains, including learning rate schedules, regularization strategies, knowledge distillation temperatures, and architecture adaptation rules.

The initialization process draws on both theoretical principles of transfer learning and empirical results from similar domain transfers in the past. For example, when transferring from natural image compression to medical image compression, the system might initialize with parameters that emphasize preservation of edge detection capabilities while preparing for adaptation to the different contrast characteristics of medical imagery. This domain-aware initialization provides a crucial starting point that significantly influences the efficiency and effectiveness of the subsequent transfer process.

In a step 1810, transform model weights from source domain to target domain using learned mappings. This step involves the systematic translation of neural network parameters from the source domain's representation space to the target domain's representation space. Unlike simple model copying, which often performs poorly across different domains, this transformation applies mapping functions that adapt weights to the statistical and structural characteristics of the target domain.

The transformation employs techniques such as correlation alignment, which adjusts weight distributions to match the covariance structure of the target domain; representation normalization, which standardizes activation ranges across domains; and structural reconfiguration, which adapts architectural elements to the target domain's characteristics. For instance, when transferring from audio to text compression, the transformation might convert temporal convolution weights to token embedding projections while preserving the abstract pattern recognition capabilities embedded in the weight relationships. These transformations enable the transferred model to effectively operate in the new domain despite significant differences in data characteristics.

In a step 1820, align gradient directions between domains to ensure consistent optimization trajectories. This step addresses a fundamental challenge in transfer learning: the optimization landscape often differs significantly between domains, causing training processes to diverge even when model initialization is appropriate. The system implements gradient alignment techniques that modify the optimization process to maintain consistent learning trajectories despite domain differences.

These alignment techniques include gradient surgery methods that identify and resolve conflicting gradient components between source and target objectives; curvature matching that adjusts second-order optimization characteristics to account for domain differences; and trajectory projection that maps successful optimization paths from the source domain onto the target domain's parameter space. For example, when transferring from sparse to dense data compression, gradient alignment might adjust for the different norm distributions that naturally arise during optimization, preventing explosive growth or vanishing of gradients in the target domain. This alignment ensures that the optimization process efficiently leverages knowledge from the source domain rather than fighting against it.

In a step 1830, apply meta-learning techniques to accelerate adaptation with minimal target domain samples. This step leverages higher-order learning principles to enable rapid adaptation to the target domain, even when limited examples are available. The system implements meta-learning algorithms that don't just transfer specific model parameters but capture the underlying process of how models adapt to new domains.

These techniques include model-agnostic meta-learning frameworks that optimize for rapid adaptation; prototypical networks that leverage source domain prototypes to guide target domain learning; and memory-augmented approaches that store and retrieve adaptation strategies from similar transfer scenarios. For instance, when adapting to a new type of sensor data with limited examples, the meta-learning system might leverage previous experience in adapting between different sensor types to identify initialization points and update rules that facilitate rapid convergence. This meta-learning approach enables effective knowledge transfer even in few-shot or zero-shot scenarios where traditional transfer learning would fail due to insufficient target domain data.

In a step 1840, monitor performance metrics during transfer to detect and mitigate negative transfer effects. This step implements continuous quality assurance throughout the transfer process to identify and address cases where knowledge transfer degrads rather than enhances performance. The system employs a comprehensive monitoring framework that tracks multiple performance indicators, including compression ratio, reconstruction quality, computational efficiency, and generalization capacity.

The monitoring process employs statistical change detection algorithms to identify performance degradation early in the transfer process; comparative analysis against source domain and baseline target domain performance; and diagnostic tools that isolate the specific components or knowledge elements causing negative transfer. When negative transfer is detected, the system implements mitigation strategies such as selective knowledge rollback, alternative source domain selection, or transfer parameter adjustment. This vigilant monitoring ensures that the transfer process enhances rather than harms the target domain compression performance.

In a step 1850, adjust learning rates and optimization parameters based on transfer confidence scores. This step involves the dynamic tuning of the learning process based on ongoing assessment of transfer effectiveness. The system generates confidence scores that quantify the reliability of knowledge transfer for different aspects of the compression model, using these scores to guide the optimization process.

In areas where transfer confidence is high, indicating that source domain knowledge is directly applicable, the system might reduce learning rates to preserve transferred knowledge while allowing minimal fine-tuning. In areas with low transfer confidence, indicating significant domain differences, the system might increase learning rates to allow more rapid adaptation away from the source domain initialization. The adjustment process employs techniques such as layer-wise adaptive rate scaling, confidence-weighted regularization, and progressive unfreezing of model components. This adaptive approach ensures efficient use of computational resources while maximizing the benefits of knowledge transfer.

In a step 1860, selectively freeze or fine-tune model components depending on domain similarity analysis. This step implements a nuanced approach to model adaptation that treats different components according to their transferability between domains. Rather than applying a uniform adaptation strategy to the entire model, the system analyzes component-level similarity between domains and applies tailored strategies accordingly.

Components with high cross-domain similarity, such as low-level feature extractors that capture universal patterns, might be frozen or minimally fine-tuned to preserve valuable knowledge. Components with low similarity, such as domain-specific prediction layers, might undergo complete retraining. The selection process employs techniques such as layerwise transferability analysis, representation similarity mapping, and functional equivalence testing. For example, when transferring from text to code compression, the system might preserve token embedding relationships while completely retraining sequence modeling components to account for the different syntactic structures. This selective approach maximizes knowledge reuse while allowing necessary adaptation.

In a step 1870, propagate successful transfer strategies back to the knowledge repository for future use. This step completes the knowledge transfer cycle by capturing insights from successful transfers to improve future operations. The system records not just the final adapted models but the complete transfer process, including initialization parameters, transformation methods, gradient alignments, and component-level adaptation strategies that proved effective.

This knowledge is structured and indexed in the repository, linked to the specific domain pair and transfer context. The system employs techniques such as transfer strategy distillation, which extracts general principles from specific transfer instances; success pattern mining, which identifies common elements across successful transfers; and adaptation strategy parameterization, which creates reusable templates for similar future transfers. This continuous learning loop enables the system to become increasingly efficient at cross-domain knowledge transfer as it gains experience across diverse domain pairs.

Through this comprehensive method for transfer learning optimization, the cross-domain knowledge transfer system enables efficient and effective knowledge sharing between compression models operating in different domains. This capability fundamentally transforms the federated two-stage compression architecture from a collection of independently trained domain-specific systems into an integrated knowledge ecosystem where advances in one domain accelerate progress across all domains. The optimization method ensures that valuable compression knowledge is effectively leveraged while appropriately adapting to the specific characteristics of each domain, maximizing both efficiency and performance throughout the federated architecture.

### Exemplary Computing Environment

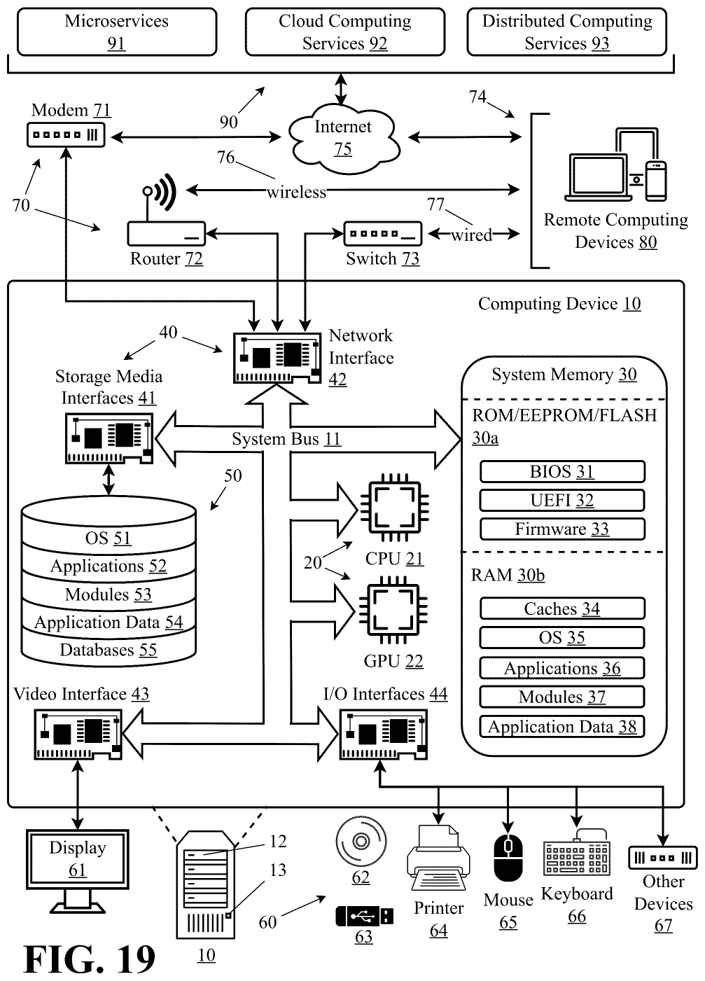

FIG. 19 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A computer system comprising a hardware memory, wherein the computer system is configured to execute software instructions stored on nontransitory machine-readable storage media that:
process input data through an edge server to generate a plurality of compressed data;
transmit the plurality of compressed data to a midserver, wherein the midserver converts the plurality of compressed data into a plurality of codewords using a codebook;
transmit the plurality of codewords to a centralized server where the plurality of codewords are converted to a plurality of universal codewords using a universal codebook;
analyze domain characteristics of the compressed data and identify relationships with existing domains using a plurality of similarity metrics;
adapt compression strategies across different domains using transfer learning optimization to accelerate model training with domain-specific examples;
train a large codeword model core using the plurality of universal codewords; and
deploy a trained large codeword model core wherein the large codeword model core receives a plurality of input data and generates a plurality of compressed outputs.

2. The system of claim 1, wherein the large codeword model core functions using a Transformer based architecture.

3. The system of claim 1, wherein the edge compresses the input data by using a Variational Autoencoder with Vector Quantization.

4. The system of claim 3, wherein the Variational Autoencoder with Vector Quantization and the large codeword model core are jointly trained.

5. A method for federated two-stage compression with federated joint learning, comprising the steps of:
processing input data through an edge server to generate a plurality of compressed data;
transmitting the plurality of compressed data to a midserver, wherein the midserver converts the plurality of compressed data into a plurality of codewords using a codebook;
transmitting the plurality of codewords to a centralized server where the plurality of codewords are converted to a plurality of universal codewords using a universal codebook;
analyzing domain characteristics of the compressed data and identify relationships with existing domains using a plurality of similarity metrics;
adapting compression strategies across different domains using transfer learning optimization to accelerate model training with domain-specific examples;
training a large codeword model core using the plurality of universal codewords; and
deploying a trained large codeword model core wherein the large codeword model core receives a plurality of input data and generates a plurality of compressed outputs.

6. The method of claim 5, wherein the large codeword model core functions using a Transformer based architecture.

7. The method of claim 5, wherein the edge compresses the input data by using a Variational Autoencoder with Vector Quantization.

8. The method of claim 7, wherein the Variational Autoencoder with Vector Quantization and the large codeword model core are jointly trained.
